(19) United States
(12) Patent Application Publication
(10) Pub. No.: US 2026/0090290 A1
(43) Pub. Date: Mar. 26, 2026

(54) STORAGE DEVICE

(71) Applicant: Kioxia Corporation, Tokyo (JP)

(72) Inventor: Yuya SATO, Fujisawa Kanagawa (JP)

(21) Appl. No.: 19/076,690

(22) Filed: Mar. 11, 2025

(30) Foreign Application Priority Data
Sep. 20, 2024 (JP) 2024-163632

(51) Int. Cl. H10N 70/00; G11C 5/06; H10B 61/00; H10B 63/00; H10N 50/10

(52) U.S. Cl. CPC H10N 70/8828; G11C 5/063; H10B 61/10; H10B 63/20; H10N 50/10; H10N 70/8822; H10N 70/8825; H10N 70/883

(57) ABSTRACT

A storage device includes a memory cell that includes: first, second, third conductive layers; a switching layer between the first and third conductive layers; and a resistive layer between the third and second conductive layers. The switching layer includes first, second, and third portions. The switching layer contains a first element and an oxide, a nitride, or an oxynitride of a second element, or the first element and a third element. The first element is at least one selected from a group consisting of Te, Se, S, Sb, and As. The second element is at least one selected from a group consisting of Zr, Al, Hf, Y, Ta, La, Ce, Mg, Si, and Ti. The third element is at least one selected from a group consisting of Zn, Sn, Ga, In, Bi, and Mg. The lengths of the first, second, and third portions are different from each other.

### CROSS-REFERENCE TO RELATED APPLICATIONS

This application is based upon and claims the benefit of priority from Japanese Patent Application No. 2024-163632, filed Sep. 20, 2024, the entire contents of which are incorporated herein by reference.

### FIELD

Embodiments described herein relate generally to a storage device.

### BACKGROUND

One type of large-capacity non-volatile storage devices is a cross-point two-terminal storage device. The cross-point two-terminal storage devices make it easier to achieve finer and mote highly integrated memory cells.

The memory cells of the cross-point two-terminal storage device includes, for example, a resistive element and a switching element. Since the memory cell includes the switching element, the current is prevented from flowing through memory cells other than the selected memory cell.

It is desirable that the switching element have excellent characteristics, such as low leakage current, high on-state current, and high reliability.

### BRIEF DESCRIPTION OF THE DRAWINGS

FIG. 1 is a block diagram of a storage device according to a first embodiment.

FIG. 2 is a cross sectional diagram schematically illustrating a memory cell of the storage device according to the first embodiment.

FIG. 3 is a cross sectional diagram schematically illustrating the memory cell of the storage device according to the first embodiment.

FIG. 4 is a cross sectional diagram schematically illustrating the memory cell of the storage device according to the first embodiment.

FIG. 5 is a cross sectional diagram schematically illustrating the memory cell of the storage device according to the first embodiment.

FIG. 6 is a diagram illustrating a problem of the storage device according to the first embodiment.

FIG. 7 is a diagram illustrating the current-voltage characteristics of a switching element in the storage device according to the first embodiment.

FIG. 8 is a cross sectional diagram schematically illustrating a memory cell of a storage device according to a comparative example.

FIG. 9 is a cross sectional diagram schematically illustrating a memory cell of a storage device according to a first modification of the first embodiment.

FIG. 10 is a cross sectional diagram schematically illustrating a memory cell of a storage device according to a second modification of the first embodiment.

FIG. 11 is a cross sectional diagram schematically illustrating a memory cell of a storage device according to a third modification of the first embodiment.

FIG. 12 is a cross sectional diagram schematically illustrating a memory cell of a storage device according to a fourth modification of the first embodiment.

FIG. 13 is a cross sectional diagram schematically illustrating a memory cell of a storage device according to a fifth modification of the first embodiment.

FIG. 14 is a cross sectional diagram schematically illustrating a memory cell of a storage device in a sixth modification of the first embodiment.

FIG. 15 is a cross sectional diagram schematically illustrating a memory cell of a storage device according to a second embodiment.

FIG. 16 is a cross sectional diagram schematically illustrating the memory cell of the storage device according to the second embodiment.

FIG. 17 is a cross sectional diagram schematically illustrating the memory cell of the storage device according to the second embodiment.

FIG. 18 is a cross sectional diagram schematically illustrating the memory cell of the storage device according to the second embodiment.

FIG. 19 is a cross sectional diagram schematically illustrating a memory cell of a storage device according to a third embodiment.

FIG. 20 is a cross sectional diagram schematically illustrating a memory cell of a storage device according to a fourth embodiment.

FIG. 21 is a cross sectional diagram schematically illustrating a memory cell of a storage device according to a fifth embodiment.

FIG. 22 is a diagram illustrating the current-voltage characteristics of a memory element in the storage device according to the fifth embodiment.

FIG. 23 is a diagram illustrating a first operation example of memory operation of the storage device according to the fifth embodiment.

FIG. 24 is a diagram illustrating a second operation example of memory operation of the storage device according to the fifth embodiment.

FIG. 25 is a diagram illustrating the current-voltage characteristics of a memory element in a storage device according to a first modification of the fifth embodiment.

FIG. 26 is a diagram illustrating a third operation example of memory operation of the storage device according to the first modification of the fifth embodiment.

FIG. 27 is a diagram illustrating a fourth operation example of memory operation of the storage device according to the first modification of the fifth embodiment.

FIG. 28 is a diagram illustrating the current-voltage characteristics of a memory element in a storage device according to a second modification of the fifth embodiment.

FIG. 29 is a diagram illustrating a fifth operation example of memory operation of the storage device according to the second modification of the fifth embodiment.

FIG. 30 is a diagram illustrating a sixth operation example of memory operation of the storage device according to the second modification of the fifth embodiment.

FIG. 31 is a diagram illustrating the current-voltage characteristics of a memory element in a storage device according to a third modification of the fifth embodiment.

FIG. 32 is a diagram illustrating a seventh operation example of memory operation of the storage device according to the third modification of the fifth embodiment.

FIG. 33 is a diagram illustrating an eighth operation example of memory operation of the storage device according to the third modification of the fifth embodiment.

FIG. 34 is a cross sectional diagram schematically illustrating a memory cell of a storage device according to a sixth embodiment.

### DETAILED DESCRIPTION

An object of the present invention is to provide a storage device that includes a switching element having excellent characteristics.

In general, according to an embodiment, a storage device in the embodiment includes a memory cell including: a first conductive layer; a second conductive layer; a third conductive layer provided between the first conductive layer and the second conductive layer; a switching layer that is provided between the first conductive layer and the third conductive layer, and includes a first portion, a second portion in contact with the first conductive layer, and a third portion in contact with the third conductive layer, the first portion being between the second portion and the third portion; and a resistive layer provided between the third conductive layer and the second conductive layer, wherein the switching layer contains a first element, and an oxide, a nitride, or an oxynitride of a second element, or the switching layer contains the first element and a third element, the first element is at least one element selected from a group consisting of tellurium (Te), selenium (Se), sulfur (S), antimony (Sb), and arsenic (As), the second element is at least one element selected from a group consisting of zirconium (Zr), aluminum (Al), hafnium (Hf), yttrium (Y), tantalum (Ta), lanthanum (La), cerium (Ce), magnesium (Mg), silicon (Si), boron (B), phosphorus (P), germanium (Ge), scandium (Sc), vanadium (V), niobium (Nb), chromium (Cr), and titanium (Ti), and the third element is at least one element selected from a group consisting of zinc (Zn), tin (Sn), gallium (Ga), indium (In), bismuth (Bi), and magnesium (Mg). In a first cross section parallel to a first direction from the first conductive layer to the second conductive layer, a first length of the first portion in a second direction perpendicular to the first direction is shorter than a second length of the second portion in the second direction, and shorter than a third length of the third portion in the second direction.

Hereinafter, embodiments of the present invention will be described with reference to the drawings. It is noted that in the following description, the same or similar elements are assigned the same symbols, and description of elements and the like having been described once will not be repeated as appropriate.

Qualitative analysis and quantitative analysis of chemical compositions constituting a storage device in the present disclosure can be performed by, for example, Rutherford backscattering spectroscopy (RBS), secondary ion mass spectroscopy (SIMS), energy dispersive X-ray spectroscopy (EDX), electron energy loss spectroscopy (EELS), etc. To measure the thicknesses of elements constituting the storage device, the distances between the components and the like, for example, a transmission electron microscope (TEM) can be used. To identify the constitutive substances of the elements making up the storage device, and measure the presence rates, bonding states, local structures (atomic distances, and coordination numbers), and chemical state, for example, X-ray photoelectron spectroscopy (XPS), X-ray absorption fine structure (XAFS), Raman spectroscopy (Raman), or EELS can be used.

### First Embodiment

A storage device according to a first embodiment includes a memory cell that includes: a first conductive layer; a second conductive layer; a third conductive layer provided between the first conductive layer and the second conductive layer; a switching layer that is provided between the first conductive layer and the third conductive layer, and includes a second portion in contact with the first conductive layer, a third portion in contact with the third conductive layer, and a first portion between the second portion and the third portion; and a resistive layer provided between the third conductive layer and the second conductive layer. The switching layer contains a first element, and an oxide, a nitride, or an oxynitride of a second element, or the switching layer contains the first element and a third element. The first element is at least one element selected from a group consisting of tellurium (Te), selenium (Se), sulfur (S), antimony (Sb), and arsenic (As). The second element is at least one element selected from a group consisting of zirconium (Zr), aluminum (Al), hafnium (Hf), yttrium (Y), tantalum (Ta), lanthanum (La), cerium (Ce), magnesium (Mg), silicon (Si), boron (B), phosphorus (P), germanium (Ge), scandium (Sc), vanadium (V), niobium (Nb), chromium (Cr), and titanium (Ti). The third element is at least one element selected from a group consisting of zinc (Zn), tin (Sn), gallium (Ga), indium (In), bismuth (Bi), and magnesium (Mg). In a first cross section parallel to a first direction connecting the first conductive layer and the second conductive layer, a first length of the first portion in a second direction perpendicular to the first direction is shorter than a second length of the second portion in the second direction, and a third length of the third portion in the second direction.

The storage device according to the first embodiment further includes a plurality of first lines, and a plurality of second lines that intersect the plurality of first lines. The memory cell is provided in a region where one of the plurality of first lines intersects one of the plurality of second lines.

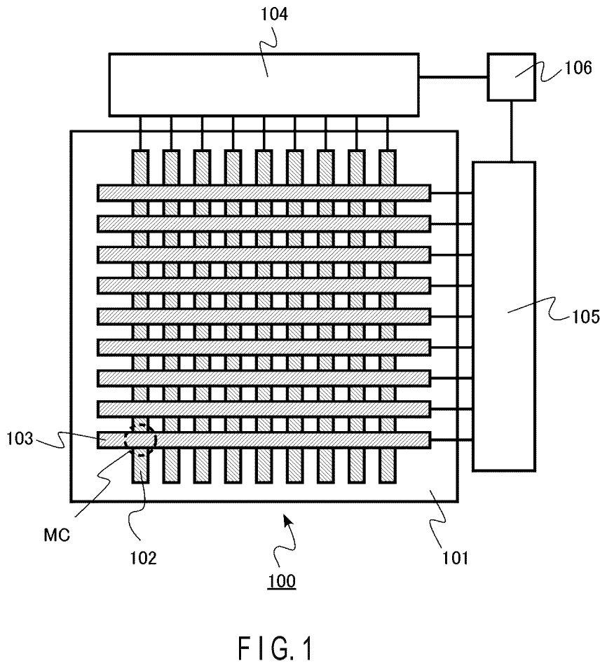

FIG. 1 is a block diagram of the storage device according to the first embodiment.

A memory cell array 100 of the storage device according to the first embodiment includes, for example, a plurality of word lines 102, and a plurality of bit lines 103 that intersect the word lines 102, via an insulating layer, on a semiconductor substrate 101. The bit lines 103 are provided on an upper layer of the word lines 102. A first control circuit 104, a second control circuit 105, and a sense circuit 106 are provided, as peripheral circuits, around the memory cell array 100.

The word lines 102 are examples of first lines. The bit lines 103 are examples of second lines.

A plurality of memory cells MC are respectively provided in regions where the word lines 102 intersect the bit lines 103. The storage device according to the first embodiment is a two-terminal magnetoresistive memory that has a cross-point structure.

Each of the word lines 102 is connected to the first control circuit 104. Each of the bit lines 103 is connected to the second control circuit 105. The sense circuit 106 is connected to the first control circuit 104 and the second control circuit 105.

The first control circuit 104 and the second control circuit 105 have, for example, functions such as of selecting a desired memory cell MC, writing data into the memory cell MC, reading data from the memory cell MC, and erasing data in the memory cell MC. When data is read, the data in the memory cell MC is read as an amount of current flowing between the word line 102 and the bit line 103, or a change in potential on the bit line 103. The sense circuit 106 has functions of determining the amount of current and determining the polarity of the data. For example, it is determined whether the data is “0” or “1”.

The first control circuit 104, the second control circuit 105, and the sense circuit 106 are made up of, for example, electronic circuits using semiconductor devices formed on the semiconductor substrate 101.

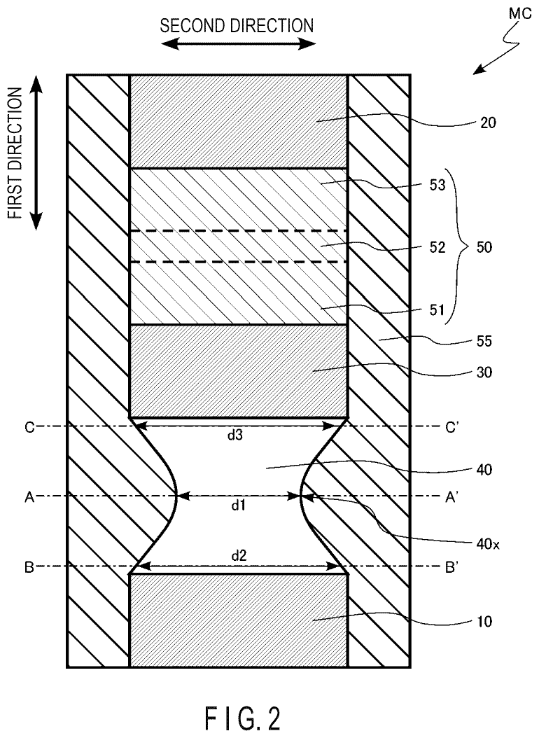

FIG. 2 is a cross sectional diagram schematically illustrating the memory cell of the storage device according to the first embodiment. FIG. 2 shows a cross section of one memory cell MC indicated by, for example, a broken-line circle in the memory cell array 100 in FIG. 1.

As shown in FIG. 2, the memory cell MC includes a lower electrode 10, an upper electrode 20, an intermediate electrode 30, a switching layer 40, a resistive layer 50, and an inter-layer insulating layer 55. The resistive layer 50 includes a fixed layer 51, a tunnel layer 52, and a free layer 53.

FIG. 2 shows a cross section parallel to a first direction that connects the lower electrode 10 and the upper electrode 20. FIG. 2 shows an example of a first cross section.

The lower electrode 10 is an example of a first conductive layer. The upper electrode 20 is an example of a second conductive layer. The intermediate electrode 30 is an example of a third conductive layer.

The lower electrode 10, the switching layer 40, and the intermediate electrode 30 constitute a switching element of the memory cell MC. The intermediate electrode 30, the resistive layer 50, and the upper electrode 20 constitute a resistive element of the memory cell MC.

The lower electrode 10 is connected to the word line 102. The lower electrode 10 is made of, for example, metal. The lower electrode 10 contains, for example, at least one substance selected from a group consisting of carbon, carbon nitride, tungsten, tungsten carbide, tungsten nitride, titanium, titanium nitride, tantalum, tantalum carbide, and tantalum nitride. The lower electrode 10 may be part of the word line 102.

The upper electrode 20 is connected to the bit line 103. The upper electrode 20 is made of, for example, metal. The upper electrode 20 contains, for example, at least one substance selected from a group consisting of carbon, carbon nitride, tungsten, tungsten carbide, tungsten nitride, titanium, titanium nitride, tantalum, tantalum carbide, and tantalum nitride. The upper electrode 20 may be part of the bit line 103.

The intermediate electrode 30 is provided between the lower electrode 10 and the upper electrode 20. The intermediate electrode 30 is made of, for example, metal. The intermediate electrode 30 contains, for example, at least one substance selected from a group consisting of carbon, carbon nitride, tungsten, tungsten carbide, tungsten nitride, titanium, titanium nitride, tantalum, tantalum carbide, and tantalum nitride.

The switching layer 40 is provided between the lower electrode 10 and the intermediate electrode 30. The thickness of the switching layer 40 in the first direction, which connects the lower electrode 10 and the upper electrode 20, ranges between, for example, 5 nm and 50 nm, inclusive. More preferably, the thickness of the switching layer 40 in the first direction ranges between, for example, 5 nm and 20 nm, inclusive.

The switching layer 40 has a function of preventing increase in semi-selected leakage current that flows through a semi-selected cell. The switching layer 40 has nonlinear current-voltage characteristics in which the current steeply rises at a specific threshold voltage.

The switching layer 40 includes a contracted portion 40x. The contracted portion 40x is a portion at which the width of the switching layer 40 is narrowed. The contracted portion 40x intervenes, for example, between two wide-width portions that have a large width, in the first direction. The contracted portion 40x is an example of a first portion.

For example, a first length (d1 in FIG. 2) of the contracted portion 40x in the second direction is shorter than a second length (d2 in FIG. 2), in the second direction, of the second portion of the switching layer 40 that is in contact with the lower electrode 10. For example, the first length (d1 in FIG. 2) of the contracted portion 40x in the second direction is shorter than a third length (d3 in FIG. 2), in the second direction, of the third portion of the switching layer 40 that is in contact with the intermediate electrode 30.

For example, the first length d1 ranges between 10% and 70% of the second length d2 and of the third length d3, inclusive. For example, the first length d1 ranges between 20% and 50% of the second length d2 and of the third length d3, inclusive.

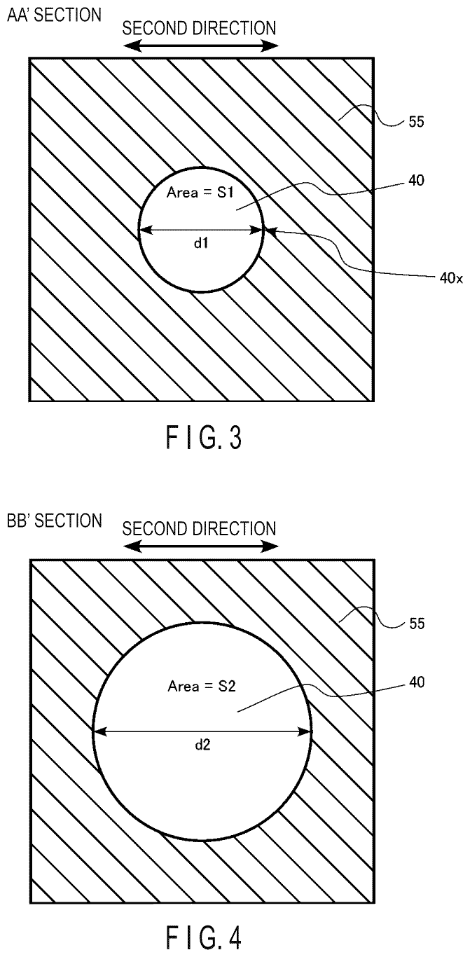

FIGS. 3, 4, and 5 are cross sectional diagrams schematically illustrating the memory cell of the storage device according to the first embodiment. FIG. 3 shows a AA′ cross section of FIG. 2. FIG. 4 shows a BB′ cross section of FIG. 2. FIG. 5 shows a CC′ cross section of FIG. 2.

FIGS. 3, 4, and 5 show cross sections perpendicular to the first direction. FIGS. 3, 4, and 5 are examples of a second cross section.

FIG. 3 shows a cross section that includes the contracted portion 40x of the switching layer 40. FIG. 4 shows a cross section that includes the second portion of the switching layer 40 that is in contact with the lower electrode 10. FIG. 5 shows a cross section that includes the third portion of the switching layer 40 that is in contact with the intermediate electrode 30.

For example, on the second cross section perpendicular to the first direction, a first area (S1 in FIG. 3) of the contracted portion 40x is smaller than a second area (S2 in FIG. 4) of the second portion of the switching layer 40 that is in contact with the lower electrode 10. For example, on the second cross section perpendicular to the first direction, the first area (S1 in FIG. 3) of the contracted portion 40x is smaller than a third area (S3 in FIG. 5) of the third portion of the switching layer 40 that is in contact with the intermediate electrode 30.

For example, the first area S1 ranges between 5% and 50% of the second area S2 and of the third area S3, inclusive. For example, the first area S1 ranges between 10% and 25% of the second area S2 and of the third area S3, inclusive.

The switching layer 40 contains, for example, a first element, and an oxide, a nitride, or an oxynitride of a second element. The switching layer 40 contains, for example: at least one substance selected from a group consisting of an oxide of a second element, a nitride of the second element, and an oxynitride of the second element; and a first element.

The first element is at least one element selected from a group consisting of tellurium (Te), selenium (Se), sulfur (S), antimony (Sb), and arsenic (As). The second element is at least one element selected from a group consisting of zirconium (Zr), aluminum (Al), hafnium (Hf), yttrium (Y), tantalum (Ta), lanthanum (La), cerium (Ce), magnesium (Mg), silicon (Si), boron (B), phosphorus (P), germanium (Ge), scandium (Sc), vanadium (V), niobium (Nb), chromium (Cr), and titanium (Ti).

The switching layer 40 contains, for example, zirconium oxide, aluminum oxide, hafnium oxide, yttrium oxide, tantalum oxide, lanthanum oxide, cerium oxide, magnesium oxide, silicon oxide, boron oxide, phosphorus oxide, germanium oxide, scandium oxide, vanadium oxide, niobium oxide, chromium oxide, or titanium oxide. The switching layer 40 contains, for example, zirconium nitride, aluminum nitride, hafnium nitride, yttrium nitride, tantalum nitride, lanthanum nitride, cerium nitride, magnesium nitride, silicon nitride, boron nitride, phosphorus nitride, germanium nitride, scandium nitride, vanadium nitride, niobium nitride, chromium nitride, or titanium nitride. The switching layer 40 contains, for example, zirconium oxynitride, aluminum oxynitride, hafnium oxynitride, yttrium oxynitride, tantalum oxynitride, lanthanum oxynitride, cerium oxynitride, magnesium oxynitride, silicon oxynitride, boron oxynitride, phosphorus oxynitride, germanium oxynitride, scandium oxynitride, vanadium oxynitride, niobium oxynitride, chromium oxynitride, or titanium oxynitride.

The switching layer 40 contains, for example: the first element; an oxide, a nitride, or an oxynitride of the second element; and the third element. The third element is at least one element selected from a group consisting of zinc (Zn), tin (Sn), gallium (Ga), indium (In), bismuth (Bi), and magnesium (Mg).

The switching layer 40 contains, for example, a compound of the first element and the third element, in addition to an oxide, a nitride, or an oxynitride of the second element.

The switching layer 40 contains, for example, the first element, and the third element. The switching layer 40 contains, for example, no second element. In this case, the switching layer 40 does not contain, for example, an oxide, a nitride, or an oxynitride. In this case, the switching layer 40 contains, for example, a compound of the first element and the third element.

The switching layer 40 contains, for example, a fourth element that is at least one element selected from a group consisting of lithium (Li), sodium (Na), potassium (K), magnesium (Mg), calcium (Ca), barium (Ba), lead (Pb), aluminum (Al), vanadium (V), iron (Fe), and tungsten (W). The switching layer 40 contains, for example: an oxide, a nitride, or an oxynitride of the second element; a compound of the first element and the third element; and the fourth element.

The atomic concentration of the fourth element contained in the switching layer 40 is lower than, for example, the atomic concentration of the second element. The atomic concentration of the fourth element contained in the switching layer 40 ranges between, for example, 1% and 30%, inclusive.

The switching layer 40 contains, for example, a fifth element that is at least one element selected from a group consisting of carbon (C), boron (B), nitrogen (N), and silicon (Si). The atomic concentration of the fifth element contained in the switching layer 40 ranges between, for example, 5% and 20%, inclusive.

The contracted portion 40x of the switching layer 40 can be formed by, for example, a manufacturing method as follows. First, sides of the lower electrode 10, the switching layer 40, and the intermediate electrode 30 are vertically patterned. Subsequently, on the side of the switching layer 40, a mask material having an opening only supporting the center portion of the switching layer 40 is formed, and the switching layer 40 is laterally etched with the mask material being adopted as a mask. Subsequently, the mask material is removed, or an opening of the mask material is embedded.

The resistive layer 50 is provided between the intermediate electrode 30 and the upper electrode 20. The resistive layer 50 includes the fixed layer 51, the tunnel layer 52, and the free layer 53. The resistive layer 50 includes a magnetic tunnel junction made up of the fixed layer 51, the tunnel layer 52, and the free layer 53.

The resistive layer 50 has a function of storing data using resistance change. The resistive layer 50 has, for example, characteristics in which the electrical resistance changes with application of a predetermined voltage.

The fixed layer 51 is a ferromagnetic body. In the fixed layer 51, the magnetization direction does not change with a predetermined write voltage, and the magnetization direction is fixed in a specific direction.

The tunnel layer 52 is an insulator. In the tunnel layer 52, electrons pass by the tunneling effect.

The free layer 53 is a ferromagnetic body. In the free layer 53, the magnetization direction changes with the predetermined write voltage. The magnetization direction of the free layer 53 can be in any of states that are a state parallel with the magnetization direction of the fixed layer 51 and a state antiparallel with the magnetization direction of the fixed layer 51. For example, by applying a voltage and causing current to flow between the intermediate electrode 30 and the upper electrode 20, the magnetization direction of the free layer 53 can be changed.

By changing the magnetization direction of the free layer 53, the electrical resistance of the resistive layer 50 changes. When the magnetization direction of the free layer 53 is in the state antiparallel with the magnetization direction of the fixed layer 51, a high-resistance state in which it is difficult for the current to flow is achieved. In contrast, when the magnetization direction of the free layer 53 is in the state parallel with the magnetization direction of the fixed layer 51, a low-resistance state in which the current easily flows is achieved. It is noted that the arrangement of the fixed layer 51 and the free layer 53 may be inverted. That is, the intermediate electrode 30, the free layer 53, the tunnel layer 52, the fixed layer 51, and the upper electrode 20 may be stacked in this order.

The inter-layer insulating layer 55 surrounds, for example, the lower electrode 10, the switching layer 40, the intermediate electrode 30, the resistive layer 50, and the upper electrode 20. The inter-layer insulating layer 55 is in contact with, for example, the side of the switching layer 40.

The inter-layer insulating layer 55 is, for example, an insulator. The inter-layer insulating layer 55 is made of, for example, silicon oxide or silicon nitride.

Next, the operation and advantageous effects of the storage device according to the first embodiment will be described.

As described above, in the storage device according to the first embodiment, by changing the magnetization direction of the free layer 53, the resistance of the resistive layer 50 changes. When the magnetization direction of the free layer 53 is in the state antiparallel with the magnetization direction of the fixed layer 51, the high-resistance state in which it is difficult for the current to flow is achieved. In contrast, when the magnetization direction of the free layer 53 is in the state parallel with the magnetization direction of the fixed layer 51, the low-resistance state in which the current easily flows is achieved.

For example, the high-resistance state of the resistive layer 50 is defined as data “1”, and the low-resistance state is defined as data “0”. The memory cell MC can maintain the different resistance states, thus allowing one-bit data of “0” and “1” to be stored. Writing into one memory cell MC is performed by applying a voltage and causing current to flow between the bit line 103 and the word line 102 that are connected to the memory cell MC.

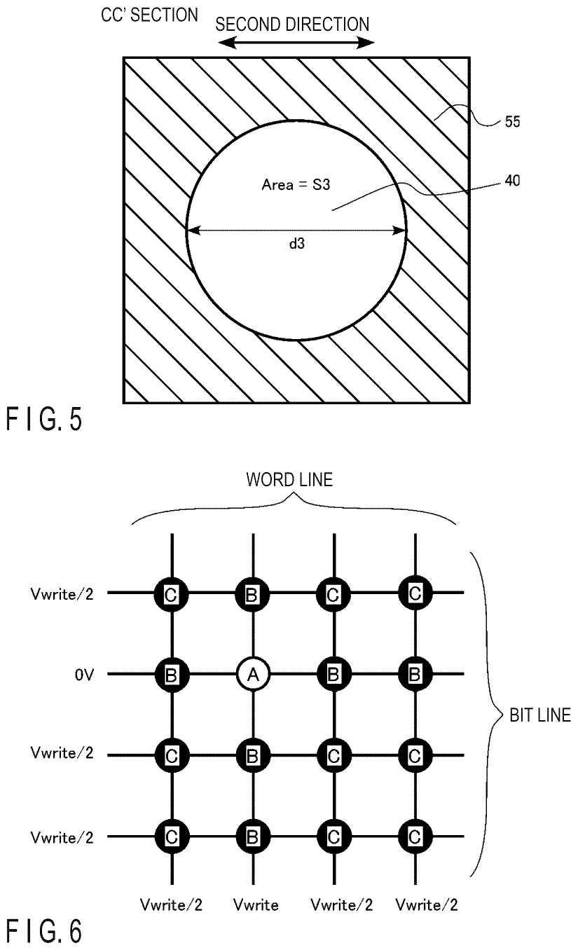

FIG. 6 is a diagram illustrating a problem of the storage device according to the first embodiment. FIG. 6 shows the voltage applied to the memory cell MC when one memory cell MC in the memory cell array is selected for a write operation. The intersections of the word lines and the bit lines indicate the respective memory cells MC.

The selected memory cell MC is a memory cell A (selected cell). A write voltage Vwrite is applied to the word line connected to the memory cell A. 0 V is applied to the bit line connected to the memory cell A.

Hereinafter, description is made using an example in which a half voltage of the write voltage (Vwrite/2) is applied to word lines and bit lines that are not connected to the memory cell A.

The voltage applied to memory cells C (unselected cells) connected to the word lines and the bit lines that are not connected to the memory cell A is 0 V. That is, no voltage is applied.

On the other hand, the half voltage of the write voltage Vwrite (Vwrite/2) is applied to memory cells B (semi-selected cells) connected to the word lines or the bit lines connected to the memory cell A. Consequently, semi-selected leakage current flows through the memory cells B (semi-selected cells).

It is noted that as an application scheme other than the above, a scheme may be used that applies the half voltage of the write voltage (Vwrite/2) to the word line connected to the memory cell A, applies the half negative voltage of the write voltage (−Vwrite/2) to the bit line, and applies 0 V to word lines and bit lines that are not connected to the memory cell A.

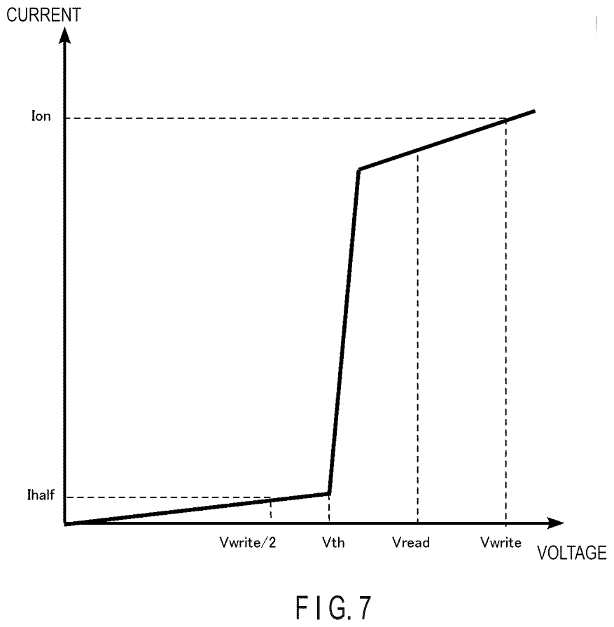

FIG. 7 is a diagram illustrating the current-voltage characteristics of the switching element in the storage device according to the first embodiment. The abscissa axis indicates the voltage applied to the switching element, and the ordinate axis indicates the current flowing through the switching element.

The switching element has nonlinear current-voltage characteristics in which the current steeply rises at a threshold voltage Vth. The threshold voltage Vth ranges, for example, between 0.5 V and 3 V, inclusive.

The write voltage Vwrite is set such that the write voltage Vwrite is higher than the threshold voltage Vth, and the half voltage of the write voltage Vwrite (Vwrite/2) is lower than the threshold voltage. The current flowing through the switching element when the write voltage Vwrite is applied is an on-state current (Ion in FIG. 7). The current flowing through the switching element when the half voltage of the write voltage Vwrite (Vwrite/2) is applied is the semi-selected leakage current (Ihalf in FIG. 7).

It is noted that for example, as shown in FIG. 7, a read voltage Vread to the memory cell MC is set to a voltage higher than the threshold voltage Vth and lower than the write voltage Vwrite. Consequently, the semi-selected leakage current flowing through the semi-selected cells during reading from the memory cell MC can also be prevented.

A possible high semi-selected leakage current increases the chip power consumption, for example. For example, the voltage drop in the line increases, and a sufficiently high voltage is not applied to the selected cell, thus making the write operation to the memory cell MC unstable. If the on-state current is low, for example, the current flowing through the selected cell becomes insufficient, thus causing insufficient writing to the memory cell MC. Consequently, it is desirable that the current-voltage characteristics of the switching element have both a low semi-selected leakage current and a high on-state current.

Furthermore, it is desirable that the current-voltage characteristics of the switching element also have high reliability. That is, it is desirable to reduce the variation in characteristics, such as variation in semi-selected leakage current and variation in on-state current, when data rewritten to the memory cell MC is repeated, to achieve high endurance characteristics high reliability.

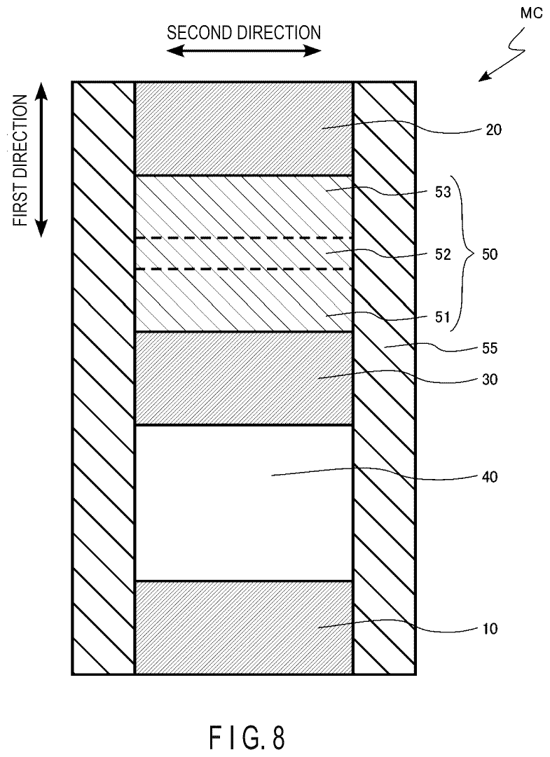

FIG. 8 is a cross sectional diagram schematically illustrating a memory cell of a storage device according to a comparative example. FIG. 8 is a diagram corresponding to FIG. 2 in the first embodiment.

The memory cell MC in the comparative example is different from the storage device according to the first embodiment in that the switching layer 40 includes no contracted portion 40x.

For example, for reduction in semi-selected leakage current in the switching element in the storage device in the comparative example, it is conceivable to reduce the cross sectional area of the current path by reducing the lateral width of the switching layer 40. In this case, if an on-state current identical to that before reduction in lateral width is intended to flow through the switching element, the on-state current density is increased by reduction in the cross sectional area of the current path.

The discussion by the inventors has clarified that when the on-state current density increases, element interdiffusion between the switching layer 40 and an electrode in contact with the switching layer 40 degrades the endurance characteristics of the switching element. Specifically, for example, it has been clarified that repetitive rewriting of data to the memory cell MC causes a short circuit failure in the switching element.

In the memory cell MC in the storage device according to the first embodiment, the switching layer 40 includes the contracted portion 40x. The contracted portion 40x reduces the cross sectional area of the current path in the switching layer 40. Consequently, the semi-selected leakage current in the switching element decreases.

In the first embodiment, by providing the contracted portion 40x in the switching layer 40, the path on the side surface of the switching layer 40 between the lower electrode 10 and the intermediate electrode 30 becomes long in comparison with the memory cell in the comparative example. The side surface of the switching layer 40 can serve as a path of the leakage current. Consequently, in the memory cell MC in the first embodiment, the semi-selected leakage current of the switching element is reduced also by increase in the path on the side surface of the switching layer 40.

On the other hand, at portions of the switching layer 40 that are in contact with the lower electrode 10 and the intermediate electrode 30, the switching layer 40 is maintained to have a large cross sectional area. Accordingly, in the portions of the switching layer 40 that are in contact with the lower electrode 10 and the intermediate electrode 30, the on-state current density is maintained to be low.

It is conceivable that the factor of the element interdiffusion between the switching layer 40 and the electrode is an increase in on-state current density at an interface portion between the switching layer 40 and the electrode. Consequently, in the switching element of the memory cell MC in the first embodiment where the area of the interface portion is large, the element interdiffusion between the switching layer 40 and the electrode is prevented, and high endurance characteristics can be achieved.

As described above, according to the first embodiment, the switching element having excellent characteristics with a low semi-selected leakage current and high reliability can be achieved. Consequently, according to the first embodiment, the storage device that includes the switching element excellent in characteristics can be achieved.

In view of reducing the semi-selected leakage current in the switching element, it is preferable that the first length (d1 in FIG. 2) of the contracted portion 40x in the second direction be equal to or shorter than 70%, more preferably 50%, of the second length (d2 in FIG. 2), in the second direction, of the second portion of the switching layer 40 that is in contact with the lower electrode 10. From a similar perspective, it is preferable that the first length (d1 in FIG. 2) of the contracted portion 40x in the second direction be equal to or shorter than 70%, more preferably 50%, of the third length (d3 in FIG. 2), in the second direction, of the third portion of the switching layer 40 that is in contact with the intermediate electrode 30.

In view of reducing the semi-selected leakage current in the switching element, it is preferable that the first area (S1 in FIG. 3) of the contracted portion 40x be equal to or smaller than 50%, more preferably 25%, of the second area (S2 in FIG. 4) of the second portion of the switching layer 40 that is in contact with the lower electrode 10. From a similar perspective, in the second cross section perpendicular to the first direction, it is preferable that the first area (S1 in FIG. 3) of the contracted portion 40x be equal to or smaller than 50%, more preferably 25%, of the third area (S3 in FIG. 5) of the third portion of the switching layer 40 that is in contact with the intermediate electrode 30.

In view of increasing the on-state current in the switching element, it is preferable that the first length (d1 in FIG. 2) of the contracted portion 40x in the second direction be equal to or longer than 10%, more preferably 20%, of the second length (d2 in FIG. 2), in the second direction, of the second portion of the switching layer 40 that is in contact with the lower electrode 10. From a similar perspective, it is preferable that the first length (d1 in FIG. 2) of the contracted portion 40x in the second direction be equal to or longer than 10%, more preferably 20%, of the third length (d3 in FIG. 2), in the second direction, of the third portion of the switching layer 40 that is in contact with the intermediate electrode 30.

In view of increasing the on-state current in the switching element, it is preferable that the first area (S1 in FIG. 3) of the contracted portion 40x be equal to or larger than 5%, more preferably 10%, of the second area (S2 in FIG. 4) of the second portion of the switching layer 40 that is in contact with the lower electrode 10. From a similar perspective, in the second cross section perpendicular to the first direction, it is preferable that the first area (S1 in FIG. 3) of the contracted portion 40x be equal to or larger than 5%, more preferably 10%, of the third area (S3 in FIG. 5) of the third portion of the switching layer 40 that is in contact with the intermediate electrode 30.

### First Modification

The storage device in a first modification of the first embodiment is different from the storage device according to the first embodiment in that the first conductive layer includes a first portion and a second portion, and the first portion contains at least one element selected from among hafnium (Hf), aluminum (Al), magnesium (Mg), zirconium (Zr), and titanium (Ti).

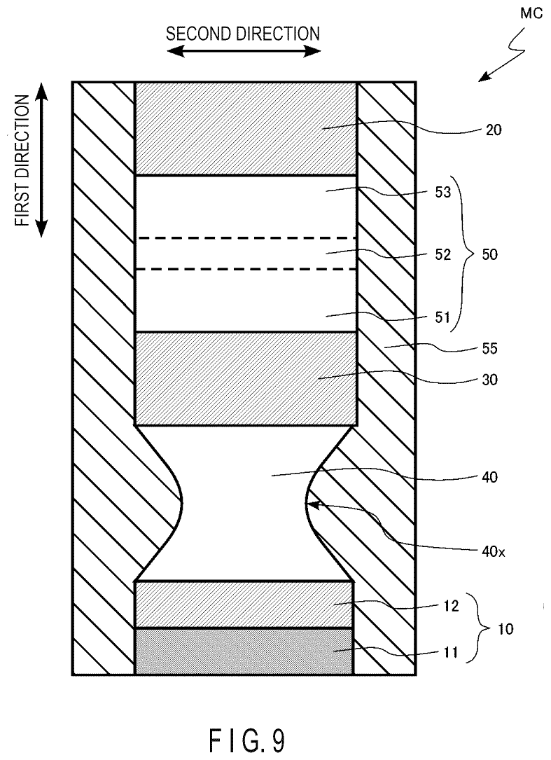

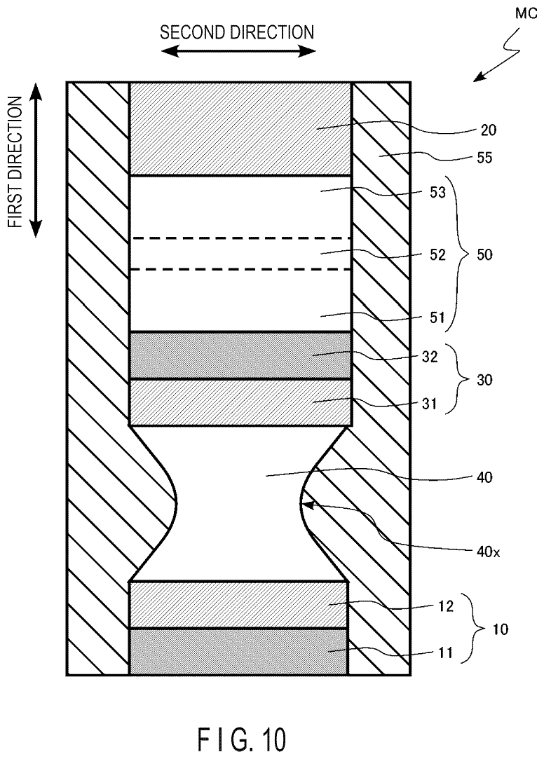

FIG. 9 is a cross sectional diagram schematically illustrating a memory cell of the storage device according to the first modification of the first embodiment. FIG. 9 is a diagram corresponding to FIG. 2 in the first embodiment. The lower electrode 10 includes a first portion 11, and a second portion 12. The second portion 12 is provided between the first portion 11 and the switching layer 40.

The first portion 11 contains at least one element selected from among hafnium (Hf), aluminum (Al), magnesium (Mg), zirconium (Zr), and titanium (Ti). The first portion 11 contains, for example, a boride of the element described above. The first portion 11 contains, for example, at least one substance selected from a group consisting of hafnium, hafnium boride, magnesium aluminum boride, zirconium, zirconium boride, and titanium boride.

The second portion 12 contains, for example, at least one substance selected from a group consisting of carbon, carbon nitride, tungsten, tungsten carbide, tungsten nitride, titanium, titanium nitride, tantalum, tantalum carbide, and tantalum nitride.

In the storage device according to the first modification of the first embodiment, the first portion 11 of the lower electrode 10 contains at least one element selected from among hafnium (Hf), aluminum (Al), magnesium (Mg), zirconium (Zr), and titanium (Ti), thereby preventing the characteristics of the resistive element from being degraded. Since the first portion 11 is not in contact with the switching layer 40, desorption of oxygen (O) from the switching layer 40 is prevented, thus preventing the characteristics of the switching element from being degraded.

As described above, according to the first modification of the first embodiment, similar to the first embodiment, the switching element having excellent characteristics with a low semi-selected leakage current and high reliability can be achieved.

### Second Modification

A storage device in a second modification of the first embodiment is different from the storage device according to the first embodiment in that a first conductive layer includes a first portion and a second portion, and the first portion contains at least one element selected from among hafnium (Hf), aluminum (Al), magnesium (Mg), zirconium (Zr), and titanium (Ti), the second conductive layer contains one element selected from among hafnium (Hf), aluminum (Al), magnesium (Mg), zirconium (Zr), and titanium (Ti), the third conductive layer includes a third portion and a fourth portion, and the fourth portion contains at least one element selected from among hafnium (Hf), aluminum (Al), magnesium (Mg), zirconium (Zr), and titanium (Ti).

FIG. 10 is a cross sectional diagram schematically illustrating a memory cell of the storage device according to the second modification of the first embodiment. FIG. 10 is a diagram corresponding to FIG. 2 in the first embodiment.

The lower electrode 10 includes a first portion 11, and a second portion 12. The second portion 12 is provided between the first portion 11 and the switching layer 40.

The first portion 11 contains at least one element selected from among hafnium (Hf), aluminum (Al), magnesium (Mg), zirconium (Zr), and titanium (Ti). The first portion 11 contains, for example, a boride of the element described above. The first portion 11 contains, for example, at least one substance selected from a group consisting of hafnium, hafnium boride, magnesium aluminum boride, zirconium, zirconium boride, and titanium boride.

The second portion 12 contains, for example, at least one substance selected from a group consisting of carbon, carbon nitride, tungsten, tungsten carbide, tungsten nitride, titanium, titanium nitride, tantalum, tantalum carbide, and tantalum nitride.

The upper electrode 20 contains at least one element selected from among hafnium (Hf), aluminum (Al), magnesium (Mg), zirconium (Zr), and titanium (Ti). The upper electrode 20 contains, for example, a boride of the element described above. The upper electrode 20 contains, for example, at least one substance selected from a group consisting of hafnium, hafnium boride, magnesium aluminum boride, zirconium, zirconium boride, and titanium boride.

The intermediate electrode 30 includes a third portion 31, and a fourth portion 32. The third portion 31 is provided between the fourth portion 32 and the switching layer 40.

The third portion 31 contains, for example, at least one substance selected from a group consisting of carbon, carbon nitride, tungsten, tungsten carbide, tungsten nitride, titanium, titanium nitride, tantalum, tantalum carbide, and tantalum nitride.

The fourth portion 32 contains at least one element selected from among hafnium (Hf), aluminum (Al), magnesium (Mg), zirconium (Zr), and titanium (Ti). The fourth portion 32 contains, for example, a boride of the element described above. The fourth portion 32 contains, for example, at least one substance selected from a group consisting of hafnium, hafnium boride, magnesium aluminum boride, zirconium, zirconium boride, and titanium boride.

In the storage device according to the second modification of the first embodiment, the first portion 11 of the lower electrode 10, the upper electrode 20, and the fourth portion 32 of the intermediate electrode 30 contain at least one element selected from among hafnium (Hf), aluminum (Al), magnesium (Mg), zirconium (Zr), and titanium (Ti), thereby preventing the characteristics of the resistive element from being degraded. The first portion 11 of the lower electrode 10, the upper electrode 20, and the fourth portion 32 of the intermediate electrode 30 are not in contact with the switching layer 40, which prevents desorption of oxygen (O) from the switching layer 40, and prevents the characteristics of the switching element from being degraded.

As described above, according to the second modification of the first embodiment, similar to the first embodiment, the switching element having excellent characteristics with a low semi-selected leakage current and high reliability can be achieved.

### Third Modification

A storage device in a third modification of the first embodiment is different from the storage device according to the first embodiment in that a first conductive layer includes a first portion, a second portion, and a fifth portion, and the first portion contains at least one element selected from among hafnium (Hf), aluminum (Al), magnesium (Mg), zirconium (Zr), and titanium (Ti), the second conductive layer contains one element selected from among hafnium (Hf), aluminum (Al), magnesium (Mg), zirconium (Zr), and titanium (Ti), the third conductive layer includes a third portion and a fourth portion, and the fourth portion contains at least one element selected from among hafnium (Hf), aluminum (Al), magnesium (Mg), zirconium (Zr), and titanium (Ti).

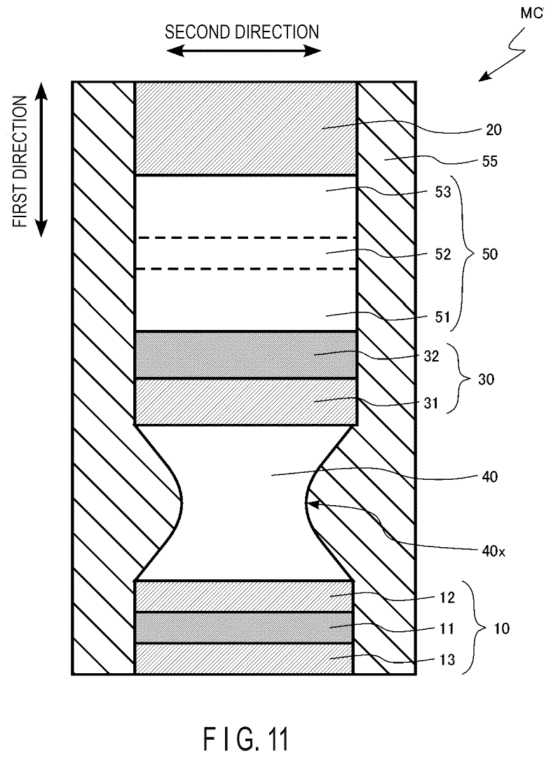

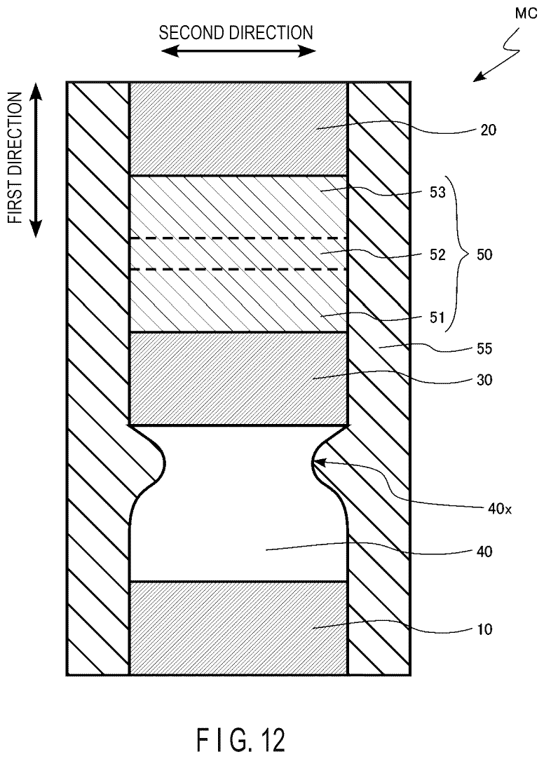

FIG. 11 is a cross sectional diagram schematically illustrating a memory cell of the storage device according to the third modification of the first embodiment. FIG. 11 is a diagram corresponding to FIG. 2 in the first embodiment.

The lower electrode 10 includes a first portion 11, a second portion 12, and a fifth portion 13. The second portion 12 is provided between the first portion 11 and the switching layer 40. The first portion 11 is provided between the fifth portion 13 and the second portion 12.

The first portion 11 contains at least one element selected from among hafnium (Hf), aluminum (Al), magnesium (Mg), zirconium (Zr), and titanium (Ti). The first portion 11 contains, for example, a boride of the element described above. The first portion 11 contains, for example, at least one substance selected from a group consisting of hafnium, hafnium boride, magnesium aluminum boride, zirconium, zirconium boride, and titanium boride.

The second portion 12 and the fifth portion 13 contain, for example, at least one substance selected from a group consisting of carbon, carbon nitride, tungsten, tungsten carbide, tungsten nitride, titanium, titanium nitride, tantalum, tantalum carbide, and tantalum nitride.

The upper electrode 20 contains at least one element selected from among hafnium (Hf), aluminum (Al), magnesium (Mg), zirconium (Zr), and titanium (Ti). The upper electrode 20 contains, for example, a boride of the element described above. The upper electrode 20 contains, for example, at least one substance selected from a group consisting of hafnium, hafnium boride, magnesium aluminum boride, zirconium, zirconium boride, and titanium boride.

The intermediate electrode 30 includes a third portion 31, and a fourth portion 32. The third portion 31 is provided between the fourth portion 32 and the switching layer 40.

The third portion 31 contains, for example, at least one substance selected from a group consisting of carbon, carbon nitride, tungsten, tungsten carbide, tungsten nitride, titanium, titanium nitride, tantalum, tantalum carbide, and tantalum nitride.

The fourth portion 32 contains at least one element selected from among hafnium (Hf), aluminum (Al), magnesium (Mg), zirconium (Zr), and titanium (Ti). The fourth portion 32 contains, for example, a boride of the element described above. The fourth portion 32 contains, for example, at least one substance selected from a group consisting of hafnium, hafnium boride, magnesium aluminum boride, zirconium, zirconium boride, and titanium boride.

In the storage device according to the third modification of the first embodiment, the first portion 11 of the lower electrode 10, the upper electrode 20, and the fourth portion 32 of the intermediate electrode 30 contain at least one element selected from among hafnium (Hf), aluminum (Al), magnesium (Mg), zirconium (Zr), and titanium (Ti), thereby preventing the characteristics of the resistive element from being degraded. The first portion 11 of the lower electrode 10, the upper electrode 20, the fourth portion 32 of the intermediate electrode 30 are not in contact with the switching layer 40, which prevents desorption of oxygen (O) from the switching layer 40, and prevents the characteristics of the switching element from being degraded.

As described above, according to the third modification of the first embodiment, similar to the first embodiment, the switching element having excellent characteristics with a low semi-selected leakage current and high reliability can be achieved.

### Fourth Modification

A storage device in a fourth modification of the first embodiment is different from the storage device according to the first embodiment in that the position of the contracted portion of the switching layer in the first direction is different.

FIG. 12 is a cross sectional diagram schematically illustrating a memory cell of the storage device according to the fourth modification of the first embodiment. FIG. 12 is a diagram corresponding to FIG. 2 in the first embodiment.

In the first direction, the contracted portion 40x is not provided at an intermediate position between the lower electrode 10 and the intermediate electrode 30, but is provided at a position close to the intermediate electrode 30. It is noted that the contracted portion 40x may be provided at a position close to the lower electrode 10 in the first direction.

As described above, according to the fourth modification of the first embodiment, similar to the first embodiment, the switching element having excellent characteristics with a low semi-selected leakage current and high reliability can be achieved.

### Fifth Modification

A storage device in a fifth modification of the first embodiment is different from the storage device according to the first embodiment in that the switching layer includes a plurality of contracted portions.

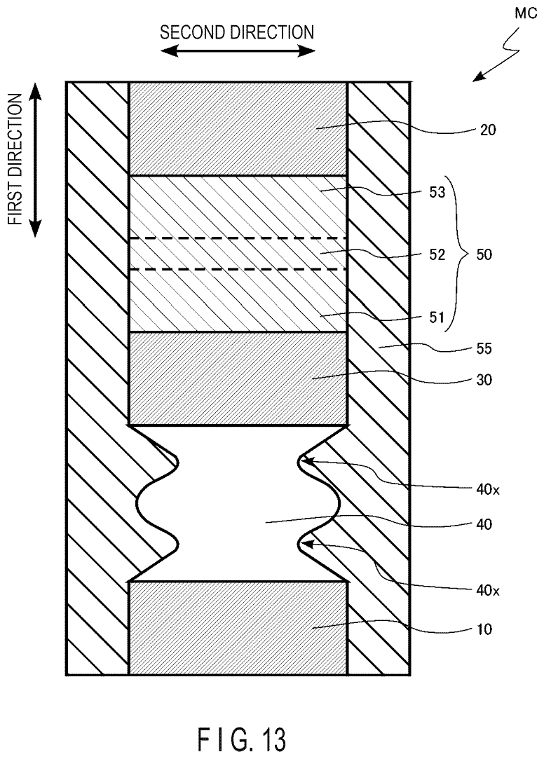

FIG. 13 is a cross sectional diagram schematically illustrating a memory cell of the storage device according to the fifth modification of the first embodiment. FIG. 13 is a diagram corresponding to FIG. 2 in the first embodiment.

Two contracted portions 40x are provided for the switching layer 40. By providing the two contracted portions 40x, the leakage current flowing through the switching layer 40 is further prevented, and the semi-selected leakage current in the switching element is reduced. By providing the two contracted portions 40x, the path on the side surface of the switching layer 40 is further elongated, and the semi-selected leakage current in the switching element is reduced.

It is noted that three or more contracted portions 40x may be provided.

As described above, according to the fifth modification of the first embodiment, similar to the first embodiment, the switching element having excellent characteristics with a low semi-selected leakage current and high reliability can be achieved.

### Sixth Modification

A storage device in a sixth modification of the first embodiment is different from the storage device according to the first embodiment in that in a first cross section parallel to the first direction connecting the first conductive layer and the second conductive layer, the atomic concentration of the first element in the first portion is different from the atomic concentration of the first element in the second portion of the switching layer that is in contact with the first conductive layer and from the atomic concentration of the first element in the third portion of the switching layer that is in contact with the third conductive layer.

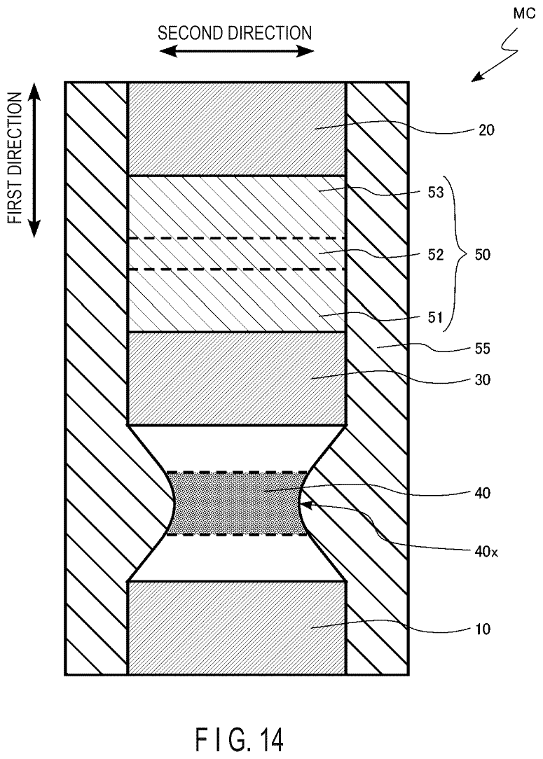

FIG. 14 is a cross sectional diagram schematically illustrating a memory cell of the storage device according to the sixth modification of the first embodiment. FIG. 14 is a diagram corresponding to FIG. 2 in the first embodiment.

The atomic concentration of the first element in the contracted portion 40x is different from the atomic concentration of the first element in the second portion of the switching layer 40 that is in contact with the lower electrode 10 and from the atomic concentration of the first element in the third portion of the switching layer 40 that is in contact with the intermediate electrode 30. For example, the atomic concentration of the first element in the contracted portion 40x is higher than the atomic concentration of the first element in the second portion of the switching layer 40 that is in contact with the lower electrode 10 and than the atomic concentration of the first element in the third portion of the switching layer 40 that is in contact with the intermediate electrode 30. For example, the atomic concentration of the first element in the contracted portion 40x is lower than the atomic concentration of the first element in the second portion of the switching layer 40 that is in contact with the lower electrode 10 and than the atomic concentration of the first element in the third portion of the switching layer 40 that is in contact with the intermediate electrode 30.

When the contracted portion 40x of the switching layer 40 is manufactured, for example, the difference in atomic concentration of the first element can provide a partial difference for the etching rate for the switching layer 40. Consequently, for example, when the switching layer 40 is laterally etched, the contracted portion 40x can be formed without using any mask material.

As described above, according to the sixth modification of the first embodiment, similar to the first embodiment, the switching element having excellent characteristics with a low semi-selected leakage current and high reliability can be achieved.

### Second Embodiment

A storage device in a second embodiment includes a memory cell that includes: a first conductive layer; a second conductive layer; a third conductive layer provided between the first conductive layer and the second conductive layer; a switching layer that is provided between the first conductive layer and the third conductive layer, and includes a first region including a second portion in contact with the first conductive layer, a third portion in contact with the third conductive layer, and a first portion between the second portion and the third portion, and a second region surrounding the first region; and a resistive layer provided between the third conductive layer and the second conductive layer. The switching layer contains a first element, and an oxide, a nitride, or an oxynitride of a second element. The first element is at least one element selected from a group consisting of tellurium (Te), selenium (Se), sulfur (S), antimony (Sb), and arsenic (As). The second element is at least one element selected from a group consisting of zirconium (Zr), aluminum (Al), hafnium (Hf), yttrium (Y), tantalum (Ta), lanthanum (La), cerium (Ce), magnesium (Mg), silicon (Si), boron (B), phosphorus (P), germanium (Ge), scandium (Sc), vanadium (V), niobium (Nb), chromium (Cr), and titanium (Ti). The atomic concentration of the first element in the first region is higher than the atomic concentration of the first element in the second region. In a first cross section parallel to a first direction connecting the first conductive layer and the second conductive layer, a first length of the first portion in a second direction perpendicular to the first direction is shorter than a second length of the second portion in the second direction, and a third length of the third portion in the second direction. The storage device according to the second embodiment is different from the storage device according to the first embodiment in that the switching layer includes a first region including a first portion, and a second region surrounding the first region. Hereinafter, the redundant description in the first embodiment is sometimes partially omitted.

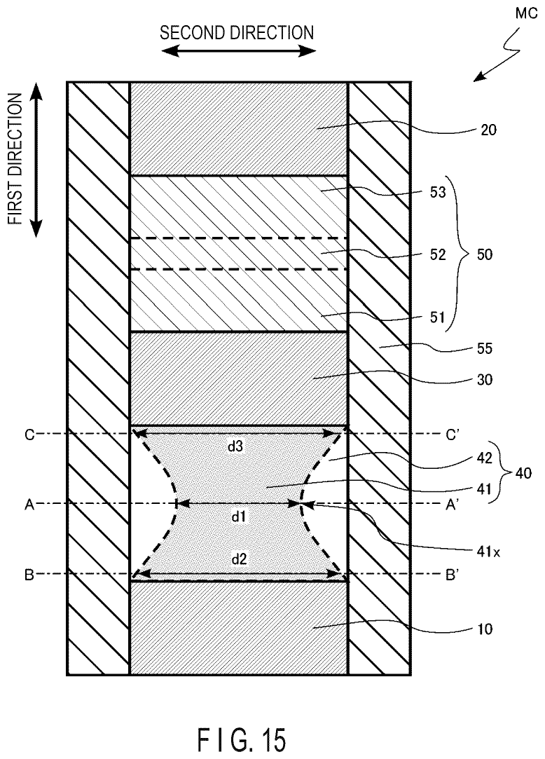

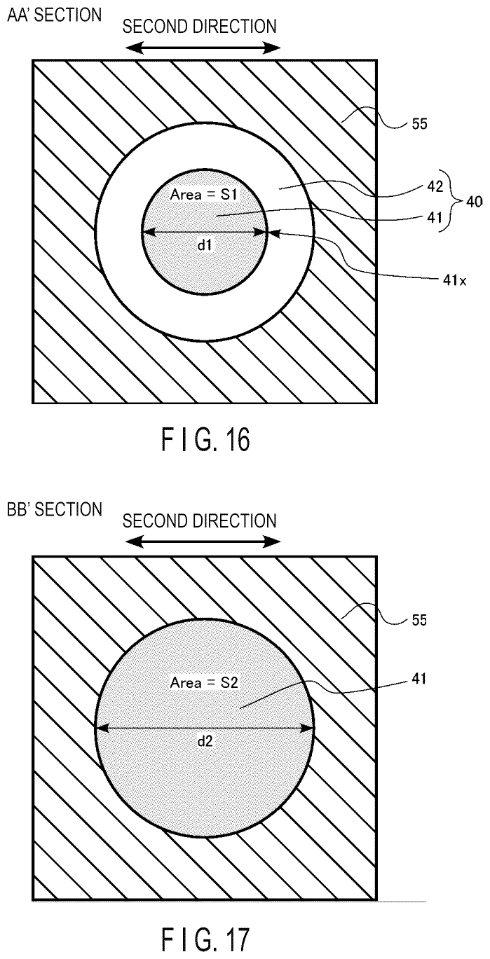

FIG. 15 is a cross sectional diagram schematically illustrating the memory cell of the storage device according to the second embodiment. FIG. 15 is a diagram corresponding to FIG. 2 in the first embodiment.

The switching layer 40 contains a first element, and an oxide, a nitride, or an oxynitride of a second element. The first element is at least one element selected from a group consisting of tellurium (Te), selenium (Se), sulfur (S), antimony (Sb), and arsenic (As). The second element is at least one element selected from a group consisting of zirconium (Zr), aluminum (Al), hafnium (Hf), yttrium (Y), tantalum (Ta), lanthanum (La), cerium (Ce), magnesium (Mg), silicon (Si), boron (B), phosphorus (P), germanium (Ge), scandium (Sc), vanadium (V), niobium (Nb), chromium (Cr), and titanium (Ti).

The switching layer 40 contains, for example: the first element; an oxide, a nitride, or an oxynitride of the second element; and the third element. The third element is at least one element selected from a group consisting of zinc (Zn), tin (Sn), gallium (Ga), indium (In), bismuth (Bi), and magnesium (Mg).

The switching layer 40 contains, for example, a fourth element that is at least one element selected from a group consisting of lithium (Li), sodium (Na), potassium (K), calcium (Ca), barium (Ba), lead (Pb), iron (Fe), and tungsten (W).

The switching layer 40 contains, for example, carbon (C).

The switching layer 40 includes the first region 41, and the second region 42. The second region 42 surrounds the first region 41. The first region 41 includes a contracted portion 41x. The contracted portion 41x is a portion at which the width of the first region 41 is narrowed. The contracted portion 41x intervenes, for example, between two wide-width portions of the first region 41 that have a large width. The contracted portion 41x is an example of a first portion.

The first region 41 and the second region 42 contain a first element, and an oxide, a nitride, or an oxynitride of a second element. The first region 41 and the second region 42 contain, for example: the first element; an oxide, a nitride, or an oxynitride of the second element; and a third element.

The first region 41 and the second region 42 contain the first element, and the second element. The first region 41 and the second region 42 contain, for example, the first element, the second element, and the third element.

The atomic concentration of the first element in the first region 41 is higher than the atomic concentration of the first element in the second region 42. Since the atomic concentration of the first element in the first region 41 is high, the first region 41 has a lower electrical resistance than the second region 42 does. Consequently, the current flowing in the switching layer 40 mainly flows through the first region 41.

In the case where the switching layer 40 contains the third element, for example, the atomic concentration of the third element in the first region 41 is higher than the atomic concentration of the third element in the second region 42. Since the atomic concentrations of the second element and the third element in the first region 41 are high, the first region 41 has a lower electrical resistance than the second region 42 does. Consequently, the current flowing in the switching layer 40 mainly flows through the first region 41.

For example, the first length (d1 in FIG. 15) of the contracted portion 41x in the second direction is shorter than the second length (d2 in FIG. 15), in the second direction, of the first region 41 at the second portion of the switching layer 40 that is in contact with the lower electrode 10. For example, the first length (d1 in FIG. 15) of the contracted portion 41x in the second direction is shorter than the third length (d3 in FIG. 15), in the second direction, of the first region 41 at the third portion of the switching layer 40 that is in contact with the intermediate electrode 30.

For example, the first length d1 ranges between 10% and 70% of the second length d2 and of the third length d3, inclusive. For example, the first length d1 ranges between 20% and 50% of the second length d2 and of the third length d3, inclusive.

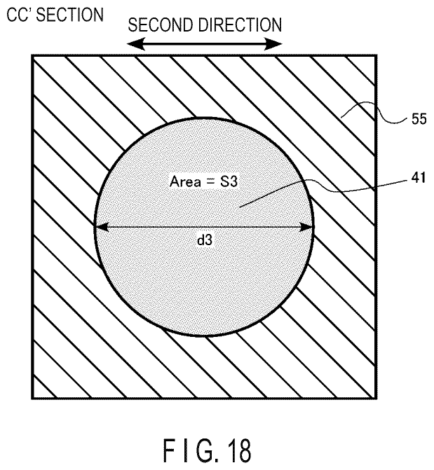

FIGS. 16, 17, and 18 are cross sectional diagrams schematically illustrating the memory cell of the storage device according to the second embodiment. FIG. 16 shows a AA′ cross section of FIG. 15. FIG. 17 shows a BB′ cross section of FIG. 15. FIG. 18 shows a CC′ cross section of FIG. 15.

FIGS. 16, 17, and 18 show cross sections perpendicular to the first direction. FIGS. 16, 17, and 18 are examples of a second cross section.

FIG. 16 shows a cross section that includes the contracted portion 41x of the first region 41 of the switching layer 40. FIG. 17 shows a cross section that includes the second portion of the switching layer 40 that is in contact with the lower electrode 10. FIG. 18 shows a cross section that includes the third portion of the switching layer 40 that is in contact with the intermediate electrode 30.

For example, in the second cross section perpendicular to the first direction, a first area (S1 in FIG. 16) of the contracted portion 41x is smaller than a second area (S2 in FIG. 17) of the first region 41 of the second portion of the switching layer 40 that is in contact with the lower electrode 10. For example, in the second cross section perpendicular to the first direction, the first area (S1 in FIG. 16) of the contracted portion 41x is smaller than a third area (S3 in FIG. 18) of the first region of the third portion of the switching layer 40 that is in contact with the intermediate electrode 30.

For example, the first area S1 ranges between 5% and 50% of the second area S2 and of the third area S3, inclusive. For example, the first area S1 ranges between 10% and 25% of the second area S2 and of the third area S3, inclusive.

The first region 41 and the second region 42 of the switching layer 40, which includes the contracted portion 41x, can be formed by, for example, a manufacturing method as described below. A switching element as in the comparative example of the first embodiment is formed. Subsequently, a predetermined bidirectional voltage stress is applied to the switching element a predetermined number of times. By applying the voltage stress, the first element diffuses in the switching layer 40. The switching layer 40 is formed that includes: the first region 41 that has the high atomic concentration of the first element and includes the contracted portion 41x; and the second region 42 that surrounds the first region 41.

Next, the operation and advantageous effects of the storage device according to the second embodiment will be described.

In the memory cell MC in the second embodiment, the first region 41 of the switching layer 40 includes the contracted portion 41x. The contracted portion 41x reduces the cross sectional area of the current path in the switching layer 40, which reduces the semi-selected leakage current in the switching element.

On the other hand, at portions of the switching layer 40 that are in contact with the lower electrode 10 and the intermediate electrode, the first region 41 is maintained to have a large cross sectional area. Accordingly, in the portions of the switching layer 40 that are in contact with the lower electrode 10 and the intermediate electrode, the on-state current density is maintained to be low. Consequently, in the switching element of the memory cell MC in the second embodiment, the element interdiffusion between the switching layer 40 and the electrode is prevented, and high endurance characteristics can be achieved.

In view of reducing the semi-selected leakage current in the switching element, it is preferable that the first length (d1 in FIG. 15) of the contracted portion 41x in the second direction be equal to or shorter than 70%, more preferably 50%, of the second length (d2 in FIG. 15), in the second direction, of the first region 41 at the second portion of the switching layer 40 that is in contact with the lower electrode 10. From a similar perspective, it is preferable that the first length (d1 in FIG. 15) of the contracted portion 41x in the second direction be equal to or shorter than 70%, more preferably 50%, of the third length (d3 in FIG. 15), in the second direction, of the first region 41 at the third portion of the switching layer 40 that is in contact with the intermediate electrode 30.

In view of reducing the semi-selected leakage current in the switching element, it is preferable that the first area (S1 in FIG. 16) of the contracted portion 41x be equal to or smaller than 50%, more preferably 25%, of the second area (S2 in FIG. 17) of the first region 41 at the second portion of the switching layer 40 that is in contact with the lower electrode 10. From a similar perspective, on the second cross section perpendicular to the first direction, it is preferable that the first area (S1 in FIG. 16) of the contracted portion 41x be equal to or smaller than 50%, more preferably 25%, of the third area (S3 in FIG. 18) of the first region 41 at the third portion of the switching layer 40 that is in contact with the intermediate electrode 30.

In view of increasing the on-state current in the switching element, it is preferable that the first length (d1 in FIG. 15) of the contracted portion 41x in the second direction be equal to or longer than 10%, more preferably 20%, of the second length (d2 in FIG. 15), in the second direction, of the first region 41 at the second portion of the switching layer 40 that is in contact with the lower electrode 10. From a similar perspective, it is preferable that the first length (d1 in FIG. 15) of the contracted portion 41x in the second direction be equal to or longer than 10%, more preferably 20%, of the third length (d3 in FIG. 15), in the second direction, of the first region 41 at the third portion of the switching layer 40 that is in contact with the intermediate electrode 30.

In view of increasing the on-state current in the switching element, it is preferable that the first area (S1 in FIG. 16) of the contracted portion 41x be equal to or larger than 5%, more preferably 10%, of the second area (S2 in FIG. 17) of the first region 41 at the second portion of the switching layer 40 that is in contact with the lower electrode 10. From a similar perspective, in the second cross section perpendicular to the first direction, it is preferable that the first area (S1 in FIG. 16) of the contracted portion 41x be equal to or larger than 5%, more preferably 10%, of the third area (S3 in FIG. 18) of the first region 41 at the third portion of the switching layer 40 that is in contact with the intermediate electrode 30.

As described above, according to the second embodiment, similar to the first embodiment, the switching element having excellent characteristics with a low semi-selected leakage current and high reliability can be achieved. Consequently, according to the second embodiment, the storage device that includes the switching element excellent in characteristics can be achieved.

### Third Embodiment

A storage device in a third embodiment is different from the storage device according to the first embodiment in that it is a resistive memory (ReRAM). Hereinafter, the redundant description in the first embodiment is partially omitted.

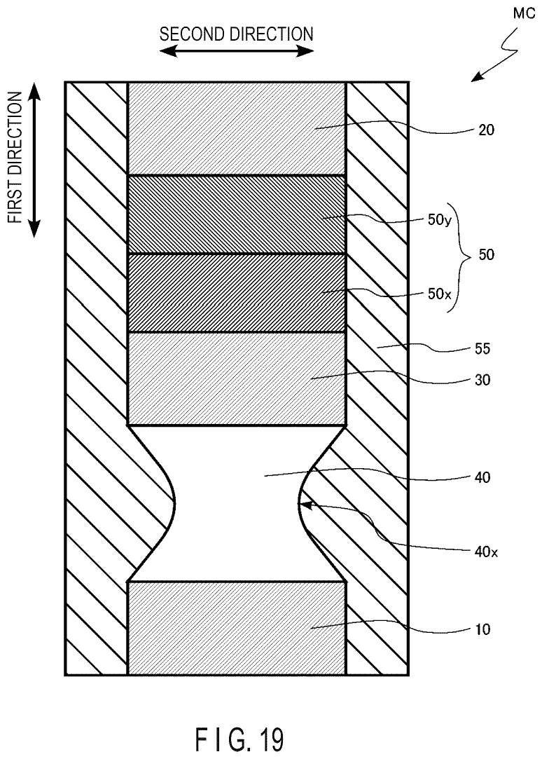

FIG. 19 is a cross sectional diagram schematically illustrating the memory cell of the storage device according to the third embodiment. FIG. 19 shows a cross section of one memory cell MC indicated by, for example, a broken-line circle in the memory cell array 100 in FIG. 1.

As shown in FIG. 19, the memory cell MC includes a lower electrode 10, an upper electrode 20, an intermediate electrode 30, a switching layer 40, a resistive layer 50, and an inter-layer insulating layer 55. The resistive layer 50 includes a high-resistance layer 50x, and a low-resistance layer 50y.

The lower electrode 10 is an example of a first conductive layer. The upper electrode 20 is an example of a second conductive layer. The intermediate electrode 30 is an example of a third conductive layer.

The lower electrode 10, the switching layer 40, and the intermediate electrode 30 constitute a switching element of the memory cell MC. The intermediate electrode 30, the resistive layer 50, and the upper electrode 20 constitute a resistive element of the memory cell MC. The switching layer 40 includes a contracted portion 40x.

The configuration of the switching layer 40 is similar to that in the storage device according to the first embodiment.

The resistive layer 50 includes the high-resistance layer 50x, and the low-resistance layer 50y.

The high-resistance layer 50x is made of, for example, a metal oxide. The high-resistance layer 50x is made of, for example, aluminum oxide, hafnium oxide, zirconium oxide, tantalum oxide, or niobium oxide.

The low-resistance layer 50y is made of, for example, a metal oxide. The low-resistance layer 50y is made of, for example, titanium oxide, niobium oxide, tantalum oxide, or tungsten oxide. The resistive layer 50 has a function of storing data using resistance change. The resistive layer 50 has, for example, characteristics in which the electrical resistance changes with application of a predetermined voltage.

By applying a voltage to the resistive layer 50, the resistive layer 50 changes from a high-resistance state to a low-resistance state, or from the low-resistance state to the high-resistance state. By applying the voltage to the resistive layer 50, oxygen ions move between the high-resistance layer 50x and the low-resistance layer 50y, and the amount of oxygen deficiency (amount of oxygen vacancy) in the low-resistance layer 50y changes. With the amount of oxygen deficiency in the low-resistance layer 50y, the conductivity of the resistive layer 50 changes. The low-resistance layer 50y is made of what is called a vacancy modulated conductive oxide. For example, the high-resistance state is defined as data “1”, and the low-resistance state is defined as data “0”. The memory cell MC can store one-bit data of “0” and “1”.

As described above, according to the storage device according to the third embodiment, similar to the first embodiment, the switching element having excellent characteristics with a low semi-selected leakage current and high reliability can be achieved. Consequently, according to the third embodiment, the storage device that includes the switching element excellent in characteristics can be achieved.

### Fourth Embodiment

A storage device in a fourth embodiment is different from the storage device according to the second embodiment in that it is a resistive memory (ReRAM). The storage device according to the fourth embodiment has a configuration similar to that of the storage device according to the third embodiment, except the switching layer. Hereinafter, the redundant description in the second embodiment and the third embodiment is partially omitted.

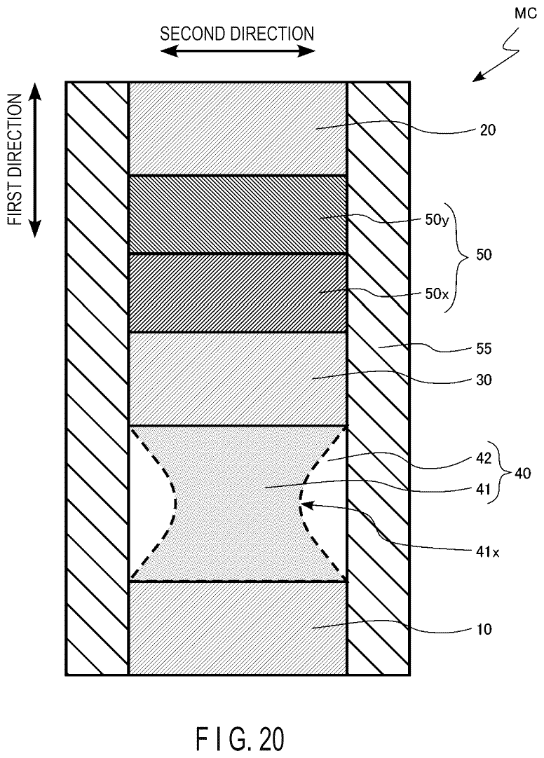

FIG. 20 is a cross sectional diagram schematically illustrating the memory cell of the storage device according to the fourth embodiment. FIG. 20 shows a cross section of one memory cell MC indicated by, for example, a broken-line circle in the memory cell array 100 in FIG. 1.

As shown in FIG. 20, the memory cell MC includes a lower electrode 10, an upper electrode 20, an intermediate electrode 30, a switching layer 40, a resistive layer 50, and an inter-layer insulating layer 55. The resistive layer 50 includes a high-resistance layer 50x, and a low-resistance layer 50y.

The lower electrode 10 is an example of a first conductive layer. The upper electrode 20 is an example of a second conductive layer. The intermediate electrode 30 is an example of a third conductive layer.

The lower electrode 10, the switching layer 40, and the intermediate electrode 30 constitute a switching element of the memory cell MC. The intermediate electrode 30, the resistive layer 50, and the upper electrode 20 constitute a resistive element of the memory cell MC. The switching layer 40 includes: a first region 41 that includes a contracted portion 41x; and a second region 42.

The configuration of the switching layer 40 is similar to that in the storage device according to the second embodiment.

The configuration of the resistive layer 50 is similar to that of the third embodiment. As described above, according to the storage device according to the fourth embodiment, similar to the second embodiment, the switching element having excellent characteristics with a low semi-selected leakage current and high reliability can be achieved. Consequently, according to the fourth embodiment, the storage device that includes the switching element excellent in characteristics can be achieved.

### Fifth Embodiment

A storage device in a fifth embodiment includes a memory cell that includes: a first conductive layer; a second conductive layer; and a memory layer that is provided between first conductive layer and the second conductive layer, and includes a second portion in contact with the first conductive layer, a third portion in contact with the second conductive layer, and a first portion between the second portion and the third portion. The memory layer contains a first element, and an oxide, a nitride, or an oxynitride of a second element, or the memory layer contains the first element and a third element. The first element is at least one element selected from a group consisting of tellurium (Te), selenium (Se), sulfur (S), antimony (Sb), and arsenic (As). The second element is at least one element selected from a group consisting of zirconium (Zr), aluminum (Al), hafnium (Hf), yttrium (Y), tantalum (Ta), lanthanum (La), cerium (Ce), magnesium (Mg), silicon (Si), boron (B), phosphorus (P), germanium (Ge), scandium (Sc), vanadium (V), niobium (Nb), chromium (Cr), and titanium (Ti). The third element is at least one element selected from a group consisting of zinc (Zn), tin (Sn), gallium (Ga), indium (In), bismuth (Bi), and magnesium (Mg).

The storage device according to the fifth embodiment further includes a plurality of first lines, and a plurality of second lines that intersect the plurality of first lines. The memory cell is provided in a region where one of the plurality of first lines intersects one of the plurality of second lines.

The storage device according to the fifth embodiment is different from the storage device according to the first embodiment in that the memory cell does not include the third conductive layer and the resistive layer, and has a configuration similar to that of the switching layer in the first embodiment as the memory layer. Hereinafter, the redundant description in the first embodiment is partially omitted.

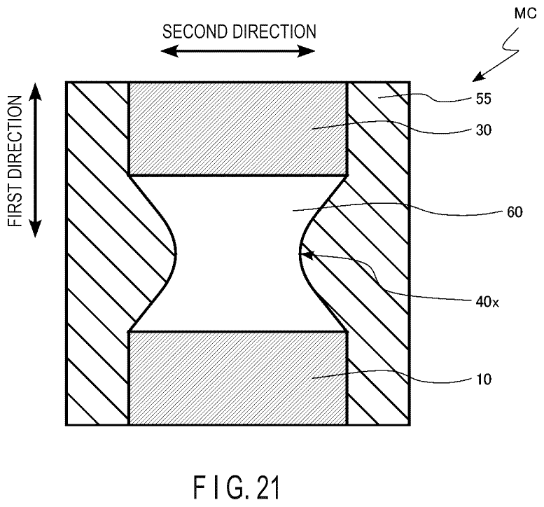

FIG. 21 is a cross sectional diagram schematically illustrating the memory cell of the storage device according to the fifth embodiment. FIG. 21 shows a cross section of one memory cell MC indicated by, for example, a broken-line circle in the memory cell array 100 in FIG. 1.

As shown in FIG. 21, the memory cell MC includes the lower electrode 10, the upper electrode 20, and the memory layer 60.

The lower electrode 10 is an example of a first conductive layer. The upper electrode 20 is an example of a second conductive layer.

The lower electrode 10, the memory layer 60, and the upper electrode 20 constitute a memory element of the memory cell MC. The memory element of the memory cell MC has a switching function, and also has a function of storing information.

The memory layer 60 has a configuration similar to that of the switching layer 40 in the first embodiment. That is, the memory layer 60 includes a contracted portion 40x. The contracted portion 40x is an example of a first portion. The memory layer 60 contains a first element, and an oxide, a nitride, or an oxynitride of a second element, or the memory layer contains the first element and a third element. The first element is at least one element selected from a group consisting of tellurium (Te), selenium (Se), sulfur (S), antimony (Sb), and arsenic (As). The second element is at least one element selected from a group consisting of zirconium (Zr), aluminum (Al), hafnium (Hf), yttrium (Y), tantalum (Ta), lanthanum (La), cerium (Ce), magnesium (Mg), silicon (Si), boron (B), phosphorus (P), germanium (Ge), scandium (Sc), vanadium (V), niobium (Nb), chromium (Cr), and titanium (Ti). The third element is at least one element selected from a group consisting of zinc (Zn), tin (Sn), gallium (Ga), indium (In), bismuth (Bi), and magnesium (Mg).

The memory layer 60 has nonlinear current-voltage characteristics in which the current steeply rises at a specific threshold voltage. The memory layer 60 has characteristics in which the threshold voltage changes with application of a predetermined voltage. The memory layer 60 has characteristics in which the electrical resistance changes with application of a predetermined voltage. In the fifth embodiment, the high-resistance state is a state where the resistance of the memory layer 60 at a read voltage is relatively high. In the fifth embodiment, the low-resistance state is a state where the resistance of the memory layer 60 at the read voltage is relatively low.

The memory layer 60 has a function of preventing increase in semi-selected leakage current that flows through a semi-selected cell. The memory layer 60 has a function of storing data using resistance change. The memory layer 60 performs the function of the switching layer 40 and the function of the resistive layer 50 in the first embodiment with a single layer.

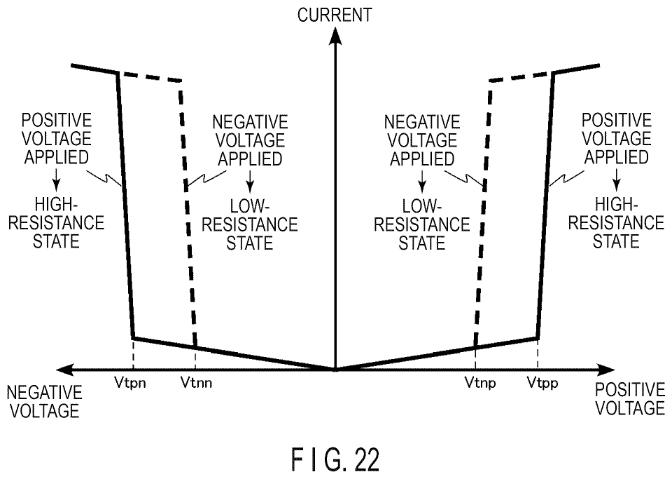

FIG. 22 is a diagram illustrating the current-voltage characteristics of the memory element in the fifth embodiment. The abscissa axis indicates the voltage applied to the memory element, and the ordinate axis indicates the current flowing through the memory element. FIG. 22 indicates, on the abscissa axis, the voltage applied to the upper electrode 20 with reference to the potential of the lower electrode 10. FIG. 22 shows the current-voltage characteristics of the memory layer 60 in the fifth embodiment. FIG. 22 shows the current-voltage characteristics of the memory cell MC in the fifth embodiment.

The memory element in the fifth embodiment exhibits different current-voltage characteristics between a case of applying a predetermined positive voltage to the upper electrode 20 and a case of applying a predetermined negative voltage to the upper electrode 20. FIG. 22 indicates the current-voltage characteristics in the case of applying the predetermined positive voltage to the upper electrode 20 with solid lines, and indicates the current-voltage characteristics in the case of applying the predetermined negative voltage to the upper electrode 20 with broken lines.

In the case of applying the predetermined positive voltage to the upper electrode 20, the current steeply rises at the first positive voltage side threshold voltage Vtpp on the positive voltage side. In the case of applying the predetermined positive voltage to the upper electrode 20, the current steeply rises at the first negative voltage side threshold voltage Vtpn on the negative voltage side.

On the other hand, in the case of applying the predetermined negative voltage to the upper electrode 20, the current steeply rises at the second positive voltage side threshold voltage Vtnp on the positive voltage side. In the case of applying the predetermined negative voltage to the upper electrode 20, the current steeply rises at the second negative voltage side threshold voltage Vtnn on the negative voltage side.

A first positive voltage side threshold voltage Vtpp is higher than a second positive voltage side threshold voltage Vtnp. A first negative voltage side threshold voltage Vtpn is lower than a second negative voltage side threshold voltage Vtnn.

The memory element in the fifth embodiment can be in each of the high-resistance state and the low-resistance state on each of the positive voltage side and the negative voltage side. In the case of applying the predetermined positive voltage to the upper electrode 20, the state is the high-resistance state on each of the positive voltage side and the negative voltage side. On the other hand, in the case of applying the predetermined negative voltage to the upper electrode 20, the state is the low-resistance state on each of the positive voltage side and the negative voltage side. Hereinafter, the high-resistance state is defined as data “1”, and the low-resistance state is defined as data “0”. The memory cell MC can store one-bit data of “0” and “1”.

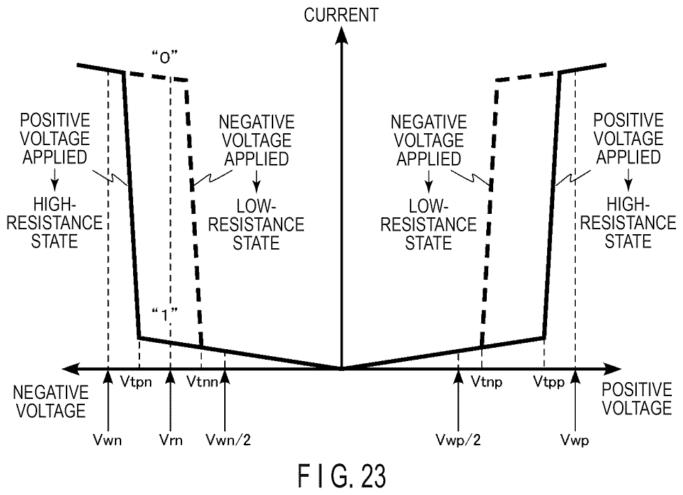

FIG. 23 is a diagram illustrating a first operation example of memory operation of the storage device according to the fifth embodiment. FIG. 23 shows a positive-side write voltage Vwp, a half voltage of the positive-side write voltage Vwp (Vwp/2), a negative-side write voltage Vwn, a half voltage of the negative-side write voltage Vwn (Vwn/2), and a negative-side read voltage Vrn when the memory operation is performed.

In the first operation example, the high-resistance state and the low-resistance state on the negative voltage side are used for the memory operation. In the first operation example, the negative-side read voltage Vrn is used as a read voltage.

When data “1” is written into the selected cell, the positive-side write voltage Vwp is applied to the upper electrode 20. The positive-side write voltage Vwp is a voltage higher than the first positive voltage side threshold voltage Vtpp. By applying the positive-side write voltage Vwp to the upper electrode 20, the high-resistance state is achieved on the negative voltage side, and data “1” is written into the selected cell.

When data “0” is written into the selected cell, the negative-side write voltage Vwn is applied to the upper electrode 20. The negative-side write voltage Vwn is a voltage lower than the first negative voltage side threshold voltage Vtpn. By applying the negative-side write voltage Vwn to the upper electrode 20, the low-resistance state is achieved on the negative voltage side, and data “0” is written into the selected cell.

In the first operation example, in the case where data stored in the selected cell is data “0” when data “1” is written into the selected cell, the current flows as long as the positive-side write voltage Vwp is higher than the second positive voltage side threshold voltage Vtnp even if it is lower than the first positive voltage side threshold voltage Vtpp. Accordingly, there is a possibility that data “1” can be written. Consequently, for example, by setting the positive-side write voltage Vwp to a voltage between the second positive voltage side threshold voltage Vtnp and the first positive voltage side threshold voltage Vtpp, a low power consumption and high reliability of the storage device can be achieved.

It is noted that when the positive-side write voltage Vwp is applied to the selected cell, the voltage Vwp/2 is applied to the semi-selected cell. It is noted that when the negative-side write voltage Vwn is applied to the selected cell, the voltage Vwn/2 is applied to the semi-selected cell. The voltage Vwp/2 is lower than the second positive voltage side threshold voltage Vtnp. The voltage Vwn/2 is higher than the second negative voltage side threshold voltage Vtnn.

Consequently, even if the semi-selected cell is in the low-resistance state, the semi-selected leakage current flowing through the semi-selected cell can be prevented. Consequently, the memory element also functions as a switching element.

When the data in the selected cell is read, the negative-side read voltage Vrn is applied to the selected cell. By detecting change in current or change in potential caused by the difference in flowing current between the case of data “1” and the case of data “0”, the data in the selected cell can be determined.

It is noted that in the case of the first operation example, irrespective of whether the data in the selected cell is data “1” or data “0”, data destruction due to application of the negative-side read voltage Vrn does not occur. In other words, in the case of the first operation example, irrespective of whether the data in the selected cell is data “1” or data “0”, nondestructive read can be performed.

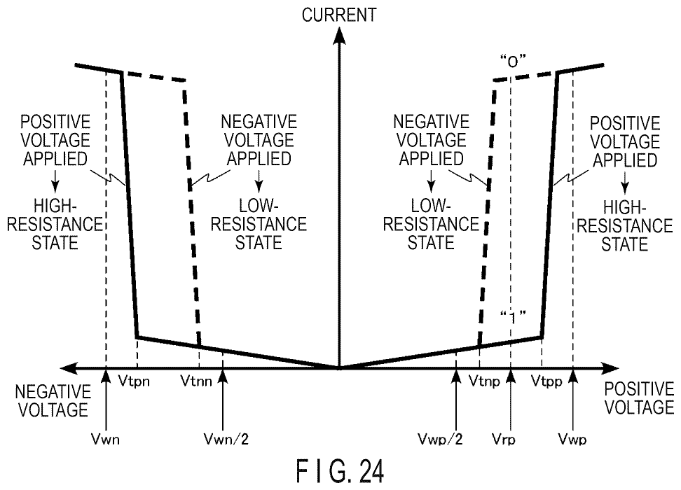

FIG. 24 is a diagram illustrating a second operation example of memory operation of the storage device according to the fifth embodiment. FIG. 24 shows a positive-side write voltage Vwp, a half voltage of the positive-side write voltage Vwp (Vwp/2), a negative-side write voltage Vwn, a half voltage of the negative-side write voltage Vwn (Vwn/2), and a positive-side read voltage Vrp when the memory operation is performed.

In the second operation example, the high-resistance state and the low-resistance state on the positive voltage side are used for the memory operation. In the second operation example, the positive-side read voltage Vrp is used as a read voltage.

When data “1” is written into the selected cell, the positive-side write voltage Vwp is applied to the upper electrode 20. The positive-side write voltage Vwp is a voltage higher than the first positive voltage side threshold voltage Vtpp. By applying the positive-side write voltage Vwp to the upper electrode 20, the high-resistance state is achieved on the positive voltage side, and data “1” is written into the selected cell.

When data “0” is written into the selected cell, the negative-side write voltage Vwn is applied to the upper electrode 20. The negative-side write voltage Vwn is a voltage lower than the first negative voltage side threshold voltage Vtpn. By applying the negative-side write voltage Vwn to the upper electrode 20, the low-resistance state is achieved on the positive voltage side, and data “0” is written into the selected cell.

In the second operation example, in the case where data stored in the selected cell is data “0” when data “1” is written into the selected cell, the current flows as long as the positive-side write voltage Vwp is higher than the second positive voltage side threshold voltage Vtnp even if it is lower than the first positive voltage side threshold voltage Vtpp. Accordingly, there is a possibility that data “1” can be written. Consequently, for example, by setting the positive-side write voltage Vwp to a voltage between the second positive voltage side threshold voltage Vtnp and the first positive voltage side threshold voltage Vtpp, a low power consumption and high reliability of the storage device can be achieved.

It is noted that when the positive-side write voltage Vwp is applied to the selected cell, the voltage Vwp/2 is applied to the semi-selected cell. It is noted that when the negative-side write voltage Vwn is applied to the selected cell, the voltage Vwn/2 is applied to the semi-selected cell. The voltage Vwp/2 is lower than the second positive voltage side threshold voltage Vtnp. The voltage Vwn/2 is higher than the second negative voltage side threshold voltage Vtnn.

Consequently, even if the semi-selected cell is in the low-resistance state, the semi-selected leakage current flowing through the semi-selected cell can be prevented. Consequently, the memory element also functions as a switching element. When the data in the selected cell is read, the positive-side read voltage Vrp is applied to the selected cell. By detecting change in current or change in potential caused by the difference in flowing current between the case of data “1” and the case of data “0”, the data in the selected cell can be determined.

It is noted that in the case of the second operation example, when the data in the selected cell is data “1”, data destruction due to application of the positive-side read voltage Vrp does not occur. In other words, in the case of the second operation example, when the data in the selected cell is data “1”, nondestructive read can be performed.

On the other hand, when the data in the selected cell is data “0”, there is a possibility that by applying the positive-side read voltage Vrp higher than the second positive voltage side threshold voltage Vtnp, current flows, and the data in the selected cell changes to data “1”. In other words, in the case of the second operation example, when the data in the selected cell is data “0”, destructive read possibly occurs. Consequently, when the data in the selected cell is data “0”, there is a possibility that rewriting of data “0” is required to maintain the data in the selected cell after data is read from the selected cell.

### First Modification

A storage device in a first modification of the fifth embodiment is different from the storage device according to the fifth embodiment in that the current-voltage characteristics of the memory element are different.

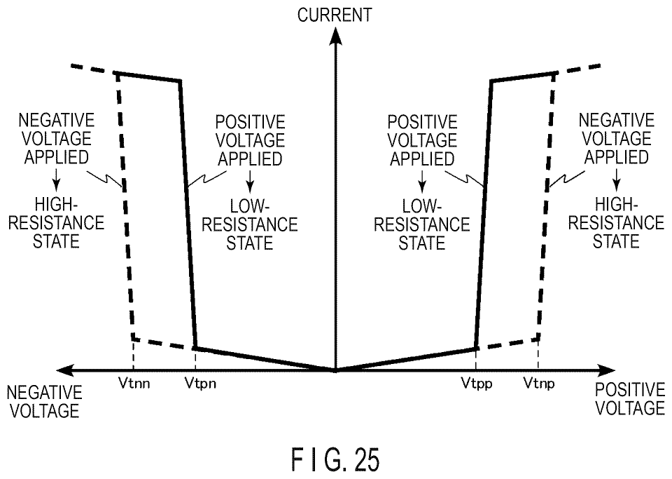

FIG. 25 is a diagram illustrating the current-voltage characteristics of the memory element according to the first modification of the fifth embodiment. The abscissa axis indicates the voltage applied to the memory element, and the ordinate axis indicates the current flowing through the memory element. FIG. 25 indicates, on the abscissa axis, the voltage applied to the upper electrode 20 with reference to the potential of the lower electrode 10. FIG. 25 is a diagram illustrating the current-voltage characteristics of the memory layer 60 in the first modification of the fifth embodiment. FIG. 25 shows the current-voltage characteristics of the memory cell MC in the first modification of the fifth embodiment.

The memory element in the first modification of the fifth embodiment exhibits different current-voltage characteristics between a case of applying a predetermined positive voltage to the upper electrode 20 and a case of applying a predetermined negative voltage to the upper electrode 20. FIG. 25 indicates the current-voltage characteristics in the case of applying the predetermined positive voltage to the upper electrode 20 with solid lines, and indicates the current-voltage characteristics in the case of applying the predetermined negative voltage to the upper electrode 20 with broken lines.

In the case of applying the predetermined positive voltage to the upper electrode 20, the current steeply rises at the first positive voltage side threshold voltage Vtpp on the positive voltage side. In the case of applying the predetermined positive voltage to the upper electrode 20, the current steeply rises at the first negative voltage side threshold voltage Vtpn on the negative voltage side.

On the other hand, in the case of applying the predetermined negative voltage to the upper electrode 20, the current steeply rises at the second positive voltage side threshold voltage Vtnp on the positive voltage side. In the case of applying the predetermined negative voltage to the upper electrode 20, the current steeply rises at the second negative voltage side threshold voltage Vtnn on the negative voltage side.

A first positive voltage side threshold voltage Vtpp is lower than a second positive voltage side threshold voltage Vtnp. A first negative voltage side threshold voltage Vtpn is higher than a second negative voltage side threshold voltage Vtnn.

The memory element in the first modification of the fifth embodiment can be in each of the high-resistance state and the low-resistance state on each of the positive voltage side and the negative voltage side. In the case of applying the predetermined positive voltage to the upper electrode 20, the state is the low-resistance state on each of the positive voltage side and the negative voltage side. On the other hand, in the case of applying the predetermined negative voltage to the upper electrode 20, the state is the high-resistance state on each of the positive voltage side and the negative voltage side. Hereinafter, the high-resistance state is defined as data “1”, and the low-resistance state is defined as data “0”. The memory cell MC can store one-bit data of “0” and “1”.

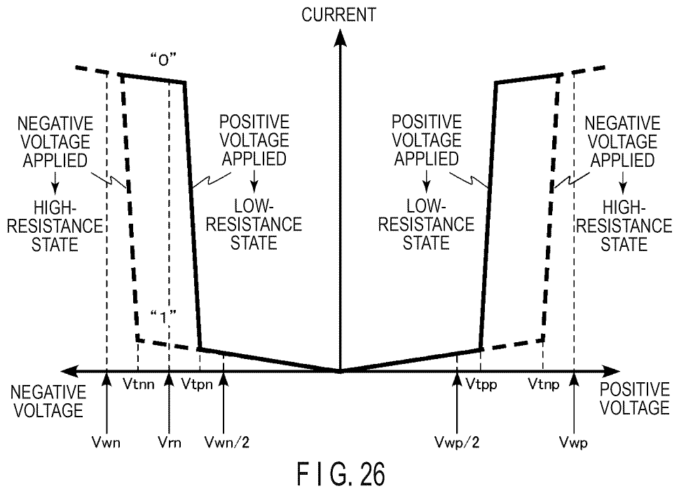

FIG. 26 is a diagram illustrating a third operation example of memory operation of the storage device according to the first modification of the fifth embodiment. FIG. 26 shows a positive-side write voltage Vwp, a half voltage of the positive-side write voltage Vwp (Vwp/2), a negative-side write voltage Vwn, a half voltage of the negative-side write voltage Vwn (Vwn/2), and a negative-side read voltage Vrn when the memory operation is performed.

In the third operation example, the high-resistance state and the low-resistance state on the negative voltage side are used for the memory operation. In the third operation example, the negative-side read voltage Vrn is used as a read voltage.

When data “1” is written into the selected cell, the negative-side write voltage Vwn is applied to the upper electrode 20. The negative-side write voltage Vwn is a voltage lower than the second negative voltage side threshold voltage Vtnn. By applying the negative-side write voltage Vwn to the upper electrode 20, the high-resistance state is achieved on the negative voltage side, and data “1” is written into the selected cell.

When data “0” is written into the selected cell, the positive-side write voltage Vwp is applied to the upper electrode 20. The positive-side write voltage Vwp is a voltage higher than the second positive voltage side threshold voltage Vtnp. By applying the positive-side write voltage Vwp to the upper electrode 20, the low-resistance state is achieved on the negative voltage side, and data “0” is written into the selected cell.

In the third operation example, in the case where data stored in the selected cell is data “0” when data “1” is written into the selected cell, the current flows as long as the negative-side write voltage Vwn is lower than the first negative voltage side threshold voltage Vtpn even if it is higher than the second negative voltage side threshold voltage Vtnn. Accordingly, there is a possibility that data “1” can be written. Consequently, for example, by setting the negative-side write voltage Vwn to a voltage between the second negative voltage side threshold voltage Vtnn and the first negative voltage side threshold voltage Vtpn, a low power consumption and high reliability of the storage device can be achieved.

It is noted that when the positive-side write voltage Vwp is applied to the selected cell, the voltage Vwp/2 is applied to the semi-selected cell. It is noted that when the negative-side write voltage Vwn is applied to the selected cell, the voltage Vwn/2 is applied to the semi-selected cell. The voltage Vwp/2 is lower than the first positive voltage side threshold voltage Vtpp. The voltage Vwn/2 is higher than the first negative voltage side threshold voltage Vtpn.

Consequently, even if the semi-selected cell is in the low-resistance state, the semi-selected leakage current flowing through the semi-selected cell can be prevented. Consequently, the memory element also functions as a switching element.

When the data in the selected cell is read, the negative-side read voltage Vrn is applied to the selected cell. By detecting change in current or change in potential caused by the difference in flowing current between the case of data “1” and the case of data “0”, the data in the selected cell can be determined.

It is noted that in the case of the third operation example, when the data in the selected cell is data “1”, data destruction due to application of the negative-side read voltage Vrn does not occur. In other words, in the case of the third operation example, when the data in the selected cell is data “1”, nondestructive read can be performed.

On the other hand, when the data in the selected cell is data “0”, there is a possibility that by applying the negative-side read voltage Vrn lower than the first negative voltage side threshold voltage Vtpn, current flows, and the data in the selected cell changes to data “1”. In other words, in the case of the third operation example, when the data in the selected cell is data “0”, destructive read possibly occurs. Consequently, when the data in the selected cell is data “0”, there is a possibility that rewriting of data “0” is required to maintain the data in the selected cell after data is read from the selected cell.

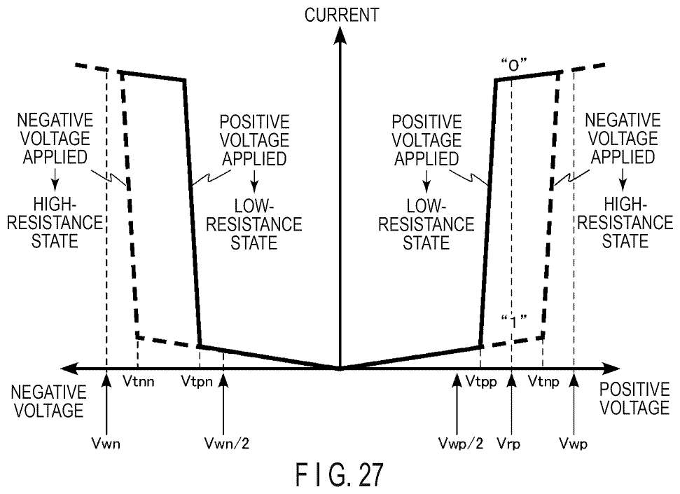

FIG. 27 is a diagram illustrating a fourth operation example of memory operation of the storage device according to the first modification of the fifth embodiment. FIG. 27 shows a positive-side write voltage Vwp, a half voltage of the positive-side write voltage Vwp (Vwp/2), a negative-side write voltage Vwn, a half voltage of the negative-side write voltage Vwn (Vwn/2), and a positive-side read voltage Vrp when the memory operation is performed.

In the fourth operation example, the high-resistance state and the low-resistance state on the positive voltage side are used for the memory operation. In the fourth operation example, the positive-side read voltage Vrp is used as a read voltage.

When data “1” is written into the selected cell, the negative-side write voltage Vwn is applied to the upper electrode 20. The negative-side write voltage Vwn is a voltage lower than the second negative voltage side threshold voltage Vtnn. By applying the negative-side write voltage Vwn to the upper electrode 20, the high-resistance state is achieved on the positive voltage side, and data “1” is written into the selected cell.

When data “0” is written into the selected cell, the positive-side write voltage Vwp is applied to the upper electrode 20. The positive-side write voltage Vwp is a voltage higher than the second positive voltage side threshold voltage Vtnp. By applying the positive-side write voltage Vwp to the upper electrode 20, the low-resistance state is achieved on the positive voltage side, and data “0” is written into the selected cell.

In the fourth operation example, in the case where data stored in the selected cell is data “0” when data “1” is written into the selected cell, the current flows as long as the negative-side write voltage Vwn is lower than the first negative voltage side threshold voltage Vtpn even if it is higher than the second negative voltage side threshold voltage Vtnn. Accordingly, there is a possibility that data “1” can be written. Consequently, for example, by setting the negative-side write voltage Vwn to a voltage between the second negative voltage side threshold voltage Vtnn and the first negative voltage side threshold voltage Vtpn, a low power consumption and high reliability of the storage device can be achieved.

It is noted that when the positive-side write voltage Vwp is applied to the selected cell, the voltage Vwp/2 is applied to the semi-selected cell. It is noted that when the negative-side write voltage Vwn is applied to the selected cell, the voltage Vwn/2 is applied to the semi-selected cell. The voltage Vwp/2 is lower than the first positive voltage side threshold voltage Vtpp. The voltage Vwn/2 is higher than the first negative voltage side threshold voltage Vtpn.

Consequently, even if the semi-selected cell is in the low-resistance state, the semi-selected leakage current flowing through the semi-selected cell can be prevented. Consequently, the memory element also functions as a switching element.

When the data in the selected cell is read, the positive-side read voltage Vrp is applied to the selected cell. By detecting change in current or change in potential caused by the difference in flowing current between the case of data “1” and the case of data “0”, the data in the selected cell can be determined.

It is noted that in the case of the fourth operation example, irrespective of whether the data in the selected cell is data “1” or data “0”, data destruction due to application of the positive-side read voltage Vrp does not occur. In other words, in the case of the fourth operation example, irrespective of whether the data in the selected cell is data “1” or data “0”, nondestructive read can be performed.

### Second Modification

A storage device in a second modification of the fifth embodiment is different from the storage device according to the fifth embodiment in that the current-voltage characteristics of the memory element are different.

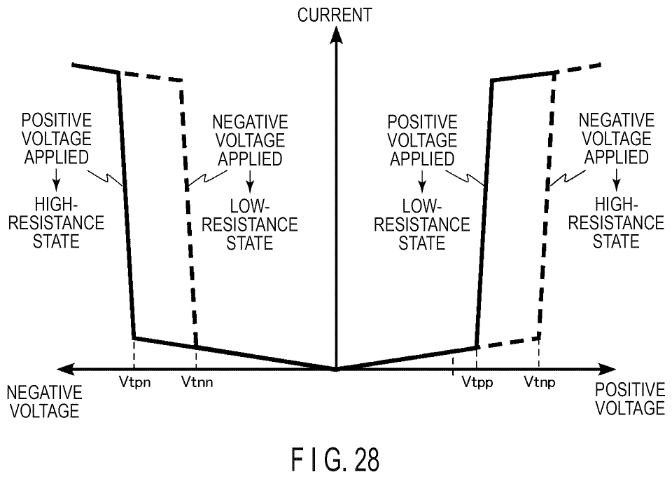

FIG. 28 is a diagram illustrating the current-voltage characteristics of the memory element according to the second modification of the fifth embodiment. The abscissa axis indicates the voltage applied to the memory element, and the ordinate axis indicates the current flowing through the memory element. FIG. 28 indicates, on the abscissa axis, the voltage applied to the upper electrode 20 with reference to the potential of the lower electrode 10. FIG. 28 is a diagram illustrating the current-voltage characteristics of the memory layer 60 in the second modification of the fifth embodiment. FIG. 28 is a diagram illustrating the current-voltage characteristics of the memory cell MC in the second modification of the fifth embodiment.

The memory element in the second modification of the fifth embodiment exhibits different current-voltage characteristics between a case of applying a predetermined positive voltage to the upper electrode 20 and a case of applying a predetermined negative voltage to the upper electrode 20. FIG. 28 indicates the current-voltage characteristics in the case of applying the predetermined positive voltage to the upper electrode 20 with solid lines, and indicates the current-voltage characteristics in the case of applying the predetermined negative voltage to the upper electrode 20 with broken lines.

In the case of applying the predetermined positive voltage to the upper electrode 20, the current steeply rises at the first positive voltage side threshold voltage Vtpp on the positive voltage side. In the case of applying the predetermined positive voltage to the upper electrode 20, the current steeply rises at the first negative voltage side threshold voltage Vtpn on the negative voltage side.

On the other hand, in the case of applying the predetermined negative voltage to the upper electrode 20, the current steeply rises at the second positive voltage side threshold voltage Vtnp on the positive voltage side. In the case of applying the predetermined negative voltage to the upper electrode 20, the current steeply rises at the second negative voltage side threshold voltage Vtnn on the negative voltage side.

The first positive voltage side threshold voltage Vtpp is lower than the second positive voltage side threshold voltage Vtnp. The first negative voltage side threshold voltage Vtpn is lower than the second negative voltage side threshold voltage Vtnn.

The memory element in the second modification of the fifth embodiment can be in each of the high-resistance state and the low-resistance state on each of the positive voltage side and the negative voltage side. In the case of applying the predetermined positive voltage to the upper electrode 20, the state is the low-resistance state on the positive voltage side, and the high-resistance state on the negative voltage side. On the other hand, in the case of applying the predetermined negative voltage to the upper electrode 20, the state is the high-resistance state on the positive voltage side, and the low-resistance state on the negative voltage side. Hereinafter, the high-resistance state is defined as data “1”, and the low-resistance state is defined as data “0”. The memory cell MC can store one-bit data of “0” and “1”.

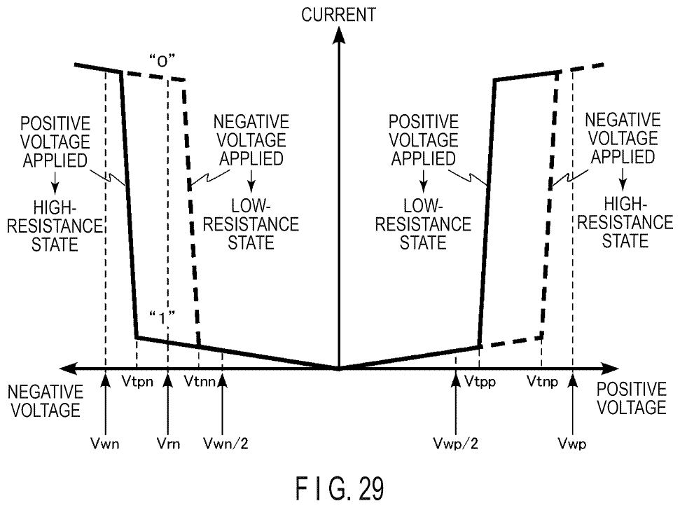

FIG. 29 is a diagram illustrating a fifth operation example of memory operation of the storage device according to the second modification of the fifth embodiment. FIG. 29 shows a positive-side write voltage Vwp, a half voltage of the positive-side write voltage Vwp (Vwp/2), a negative-side write voltage Vwn, a half voltage of the negative-side write voltage Vwn (Vwn/2), and a negative-side read voltage Vrn when the memory operation is performed.

In the fifth operation example, the high-resistance state and the low-resistance state on the negative voltage side are used for the memory operation. In the fifth operation example, the negative-side read voltage Vrn is used as a read voltage.

When data “1” is written into the selected cell, the positive-side write voltage Vwp is applied to the upper electrode 20. The positive-side write voltage Vwp is a voltage higher than the second positive voltage side threshold voltage Vtnp. By applying the positive-side write voltage Vwp to the upper electrode 20, the high-resistance state is achieved on the negative voltage side, and data “1” is written into the selected cell.

When data “0” is written into the selected cell, the negative-side write voltage Vwn is applied to the upper electrode 20. The negative-side write voltage Vwn is a voltage lower than the first negative voltage side threshold voltage Vtpn. By applying the negative-side write voltage Vwn to the upper electrode 20, the low-resistance state is achieved on the negative voltage side, and data “0” is written into the selected cell.

It is noted that when the positive-side write voltage Vwp is applied to the selected cell, the voltage Vwp/2 is applied to the semi-selected cell. It is noted that when the negative-side write voltage Vwn is applied to the selected cell, the voltage Vwn/2 is applied to the semi-selected cell. The voltage Vwp/2 is lower than the first positive voltage side threshold voltage Vtpp. The voltage Vwn/2 is higher than the second negative voltage side threshold voltage Vtnn.

Consequently, even if the semi-selected cell is in the low-resistance state, the semi-selected leakage current flowing through the semi-selected cell can be prevented. Consequently, the memory element also functions as a switching element.

When the data in the selected cell is read, the negative-side read voltage Vrn is applied to the selected cell. By detecting change in current or change in potential caused by the difference in flowing current between the case of data “1” and the case of data “0”, the data in the selected cell can be determined.

It is noted that in the case of the fifth operation example, irrespective of whether the data in the selected cell is data “1” or data “0”, data destruction due to application of the negative-side read voltage Vrn does not occur. In other words, in the case of the fifth operation example, irrespective of whether the data in the selected cell is data “1” or data “0”, nondestructive read can be performed.

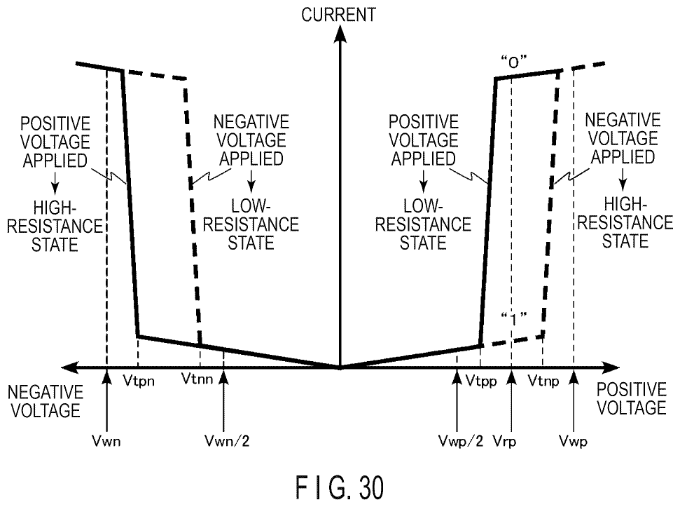

FIG. 30 is a diagram illustrating a sixth operation example of memory operation of the storage device according to the second modification of the fifth embodiment. FIG. 30 shows a positive-side write voltage Vwp, a half voltage of the positive-side write voltage Vwp (Vwp/2), a negative-side write voltage Vwn, a half voltage of the negative-side write voltage Vwn (Vwn/2), and a positive-side read voltage Vrp when the memory operation is performed.

In the sixth operation example, the high-resistance state and the low-resistance state on the positive voltage side are used for the memory operation. In the sixth operation example, the positive-side read voltage Vrp is used as a read voltage.

When data “1” is written into the selected cell, the negative-side write voltage Vwn is applied to the upper electrode 20. The negative-side write voltage Vwn is a voltage lower than the first negative voltage side threshold voltage Vtpn. By applying the negative-side write voltage Vwn to the upper electrode 20, the high-resistance state is achieved on the positive voltage side, and data “1” is written into the selected cell.

When data “0” is written into the selected cell, the positive-side write voltage Vwp is applied to the upper electrode 20. The positive-side write voltage Vwp is a voltage higher than the second positive voltage side threshold voltage Vtnp. By applying the positive-side write voltage Vwp to the upper electrode 20, the low-resistance state is achieved on the positive voltage side, and data “0” is written into the selected cell.

It is noted that when the positive-side write voltage Vwp is applied to the selected cell, the voltage Vwp/2 is applied to the semi-selected cell. It is noted that when the negative-side write voltage Vwn is applied to the selected cell, the voltage Vwn/2 is applied to the semi-selected cell. The voltage Vwp/2 is lower than the first positive voltage side threshold voltage Vtpp. The voltage Vwn/2 is higher than the second negative voltage side threshold voltage Vtnn.

Consequently, even if the semi-selected cell is in the low-resistance state, the semi-selected leakage current flowing through the semi-selected cell can be prevented. Consequently, the memory element also functions as a switching element.

When the data in the selected cell is read, the positive-side read voltage Vrp is applied to the selected cell. By detecting change in current or change in potential caused by the difference in flowing current between the case of data “1” and the case of data “0”, the data in the selected cell can be determined.

It is noted that in the case of the sixth operation example, irrespective of whether the data in the selected cell is data “1” or data “0”, data destruction due to application of the positive-side read voltage Vrp does not occur. In other words, in the case of the sixth operation example, irrespective of whether the data in the selected cell is data “1” or data “0”, nondestructive read can be performed.

### Third Modification

A storage device in a third modification of the fifth embodiment is different from the storage device according to the fifth embodiment in that the current-voltage characteristics of the memory element are different.

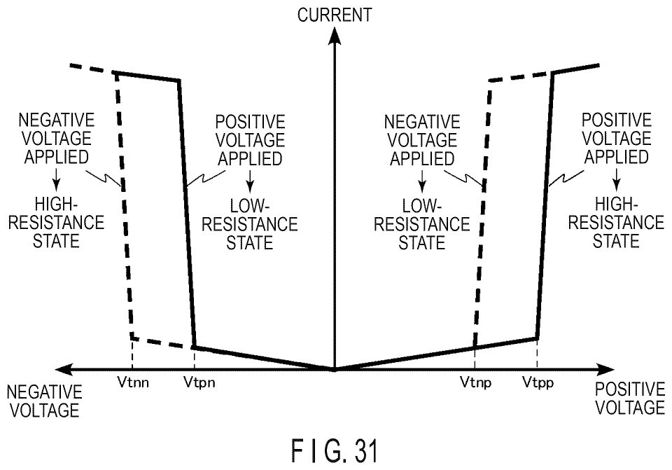

FIG. 31 is a diagram illustrating the current-voltage characteristics of the memory element in the third modification of the fifth embodiment. The abscissa axis indicates the voltage applied to the memory element, and the ordinate axis indicates the current flowing through the memory element. FIG. 31 indicates, on the abscissa axis, the voltage applied to the upper electrode 20 with reference to the potential of the lower electrode 10. FIG. 31 is a diagram illustrating the current-voltage characteristics of the memory layer 60 in the third modification of the fifth embodiment. FIG. 31 is a diagram illustrating the current-voltage characteristics of the memory cell MC in the third modification of the fifth embodiment.

The memory element in the third modification of the fifth embodiment exhibits different current-voltage characteristics between a case of applying a predetermined positive voltage to the upper electrode 20 and a case of applying a predetermined negative voltage to the upper electrode 20. FIG. 31 indicates the current-voltage characteristics in the case of applying the predetermined positive voltage to the upper electrode 20 with solid lines, and indicates the current-voltage characteristics in the case of applying the predetermined negative voltage to the upper electrode 20 with broken lines.

In the case of applying the predetermined positive voltage to the upper electrode 20, the current steeply rises at the first positive voltage side threshold voltage Vtpp on the positive voltage side. In the case of applying the predetermined positive voltage to the upper electrode 20, the current steeply rises at the first negative voltage side threshold voltage Vtpn on the negative voltage side.

On the other hand, in the case of applying the predetermined negative voltage to the upper electrode 20, the current steeply rises at the second positive voltage side threshold voltage Vtnp on the positive voltage side. In the case of applying the predetermined negative voltage to the upper electrode 20, the current steeply rises at the second negative voltage side threshold voltage Vtnn on the negative voltage side.

The first positive voltage side threshold voltage Vtpp is higher than the second positive voltage side threshold voltage Vtnp. The first negative voltage side threshold voltage Vtpn is higher than the second negative voltage side threshold voltage Vtnn.

The memory element in the third modification of the fifth embodiment can be in each of the high-resistance state and the low-resistance state on each of the positive voltage side and the negative voltage side. In the case of applying the predetermined positive voltage to the upper electrode 20, the state is the high-resistance state on the positive voltage side, and the low-resistance state on the negative voltage side. On the other hand, in the case of applying the predetermined negative voltage to the upper electrode 20, the state is the low-resistance state on the positive voltage side, and the high-resistance state on the negative voltage side. Hereinafter, the high-resistance state is defined as data “1”, and the low-resistance state is defined as data “0”. The memory cell MC can store one-bit data of “0” and “1”.

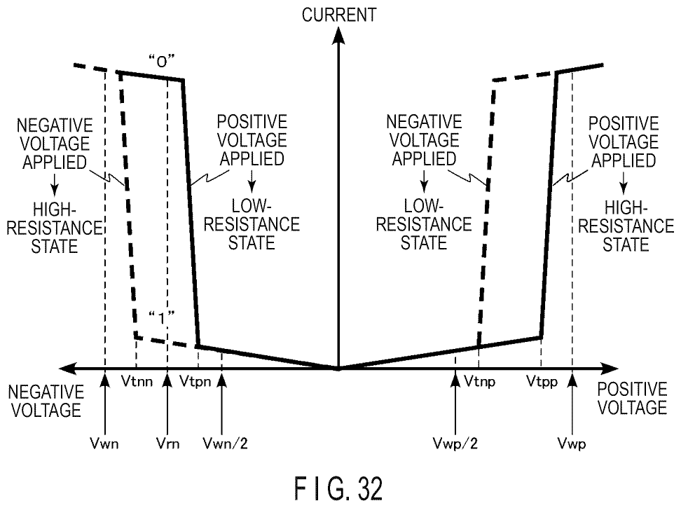

FIG. 32 is a diagram illustrating a seventh operation example of memory operation of the storage device according to the third modification of the fifth embodiment. FIG. 32 shows a positive-side write voltage Vwp, a half voltage of the positive-side write voltage Vwp (Vwp/2), a negative-side write voltage Vwn, a half voltage of the negative-side write voltage Vwn (Vwn/2), and a negative-side read voltage Vrn when the memory operation is performed.

In the seventh operation example, the high-resistance state and the low-resistance state on the negative voltage side are used for the memory operation. In the seventh operation example, the negative-side read voltage Vrn is used as a read voltage.

When data “1” is written into the selected cell, the negative-side write voltage Vwn is applied to the upper electrode 20. The negative-side write voltage Vwn is a voltage lower than the second negative voltage side threshold voltage Vtnn. By applying the negative-side write voltage Vwn to the upper electrode 20, the high-resistance state is achieved on the negative voltage side, and data “1” is written into the selected cell.

When data “0” is written into the selected cell, the positive-side write voltage Vwp is applied to the upper electrode 20. The positive-side write voltage Vwp is a voltage higher than the first positive voltage side threshold voltage Vtpp. By applying the positive-side write voltage Vwp to the upper electrode 20, the low-resistance state is achieved on the negative voltage side, and data “0” is written into the selected cell.

In the seventh operation example, in the case where data stored in the selected cell is data “0” when data “1” is written into the selected cell, the current flows as long as the negative-side write voltage Vwn is lower than the first negative voltage side threshold voltage Vtpn even if it is higher than the second negative voltage side threshold voltage Vtnn. Accordingly, there is a possibility that data “1” can be written. Consequently, for example, by setting the negative-side write voltage Vwn to a voltage between the second negative voltage side threshold voltage Vtnn and the first negative voltage side threshold voltage Vtpn, a low power consumption and high reliability of the storage device can be achieved.

In the seventh operation example, in the case where data stored in the selected cell is data “1” when data “0” is written into the selected cell, the current flows as long as the positive-side write voltage Vwp is higher than the second positive voltage side threshold voltage Vtnp even if it is lower than the first positive voltage side threshold voltage Vtpp. Accordingly, there is a possibility that data “0” can be written. Consequently, for example, by setting the positive-side write voltage Vwp to a voltage between the second positive voltage side threshold voltage Vtnp and the first positive voltage side threshold voltage Vtpp, a low power consumption and high reliability of the storage device can be achieved.

It is noted that when the positive-side write voltage Vwp is applied to the selected cell, the voltage Vwp/2 is applied to the semi-selected cell. It is noted that when the negative-side write voltage Vwn is applied to the selected cell, the voltage Vwn/2 is applied to the semi-selected cell. The voltage Vwp/2 is lower than the second positive voltage side threshold voltage Vtnp. The voltage Vwn/2 is higher than the first negative voltage side threshold voltage Vtpn.

Consequently, even if the semi-selected cell is in the low-resistance state, the semi-selected leakage current flowing through the semi-selected cell can be prevented. Consequently, the memory element also functions as a switching element.

When the data in the selected cell is read, the negative-side read voltage Vrn is applied to the selected cell. By detecting change in current or change in potential caused by the difference in flowing current between the case of data “1” and the case of data “0”, the data in the selected cell can be determined.

It is noted that in the case of the seventh operation example, when the data in the selected cell is data “1”, data destruction due to application of the negative-side read voltage Vrn does not occur. In other words, in the case of the seventh operation example, when the data in the selected cell is data “1”, nondestructive read can be performed.

On the other hand, when the data in the selected cell is data “0”, there is a possibility that by applying the negative-side read voltage Vrn lower than the first negative voltage side threshold voltage Vtpn, current flows, and the data in the selected cell changes to data “1”. In other words, in the case of the seventh operation example, when the data in the selected cell is data “0”, destructive read possibly occurs. Consequently, when the data in the selected cell is data “0”, there is a possibility that rewriting of data “0” is required to maintain the data in the selected cell after data is read from the selected cell.

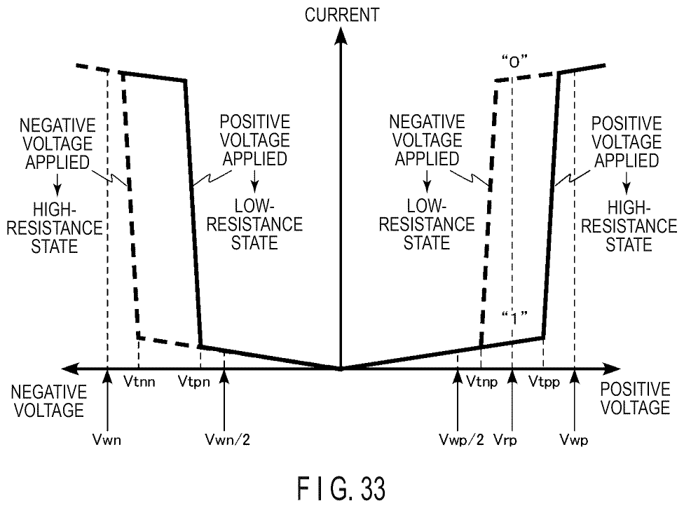

FIG. 33 is a diagram illustrating an eighth operation example of memory operation of the storage device according to the third modification of the fifth embodiment. FIG. 33 shows a positive-side write voltage Vwp, a half voltage of the positive-side write voltage Vwp (Vwp/2), a negative-side write voltage Vwn, a half voltage of the negative-side write voltage Vwn (Vwn/2), and a positive-side read voltage Vrp when the memory operation is performed.

In the eighth operation example, the high-resistance state and the low-resistance state on the positive voltage side are used for the memory operation. In the eighth operation example, the positive-side read voltage Vrp is used as a read voltage.

When data “1” is written into the selected cell, the positive-side write voltage Vwp is applied to the upper electrode 20. The positive-side write voltage Vwp is a voltage higher than the first positive voltage side threshold voltage Vtpp. By applying the positive-side write voltage Vwp to the upper electrode 20, the high-resistance state is achieved on the positive voltage side, and data “1” is written into the selected cell.

When data “0” is written into the selected cell, the negative-side write voltage Vwn is applied to the upper electrode 20. The negative-side write voltage Vwn is a voltage lower than the second negative voltage side threshold voltage Vtnn. By applying the negative-side write voltage Vwn to the upper electrode 20, the low-resistance state is achieved on the positive voltage side, and data “0” is written into the selected cell.

In the eighth operation example, in the case where data stored in the selected cell is data “0” when data “1” is written into the selected cell, the current flows as long as the positive-side write voltage Vwp is higher than the second positive voltage side threshold voltage Vtnp even if it is lower than the first positive voltage side threshold voltage Vtpp. Accordingly, there is a possibility that data “1” can be written. Consequently, for example, by setting the positive-side write voltage Vwp to a voltage between the second positive voltage side threshold voltage Vtnp and the first positive voltage side threshold voltage Vtpp, a low power consumption and high reliability of the storage device can be achieved.

In the eighth operation example, in the case where data stored in the selected cell is data “1” when data “0” is written into the selected cell, the current flows as long as the negative-side write voltage Vwn is lower than the first negative voltage side threshold voltage Vtpn even if it is higher than the second negative voltage side threshold voltage Vtnn. Accordingly, there is a possibility that data “0” can be written. Consequently, for example, by setting the negative-side write voltage Vwn to a voltage between the second negative voltage side threshold voltage Vtnn and the first negative voltage side threshold voltage Vtpn, a low power consumption and high reliability of the storage device can be achieved.

It is noted that when the positive-side write voltage Vwp is applied to the selected cell, the voltage Vwp/2 is applied to the semi-selected cell. It is noted that when the negative-side write voltage Vwn is applied to the selected cell, the voltage Vwn/2 is applied to the semi-selected cell. The voltage Vwp/2 is lower than the second positive voltage side threshold voltage Vtnp. The voltage Vwn/2 is higher than the first negative voltage side threshold voltage Vtpn.

Consequently, even if the semi-selected cell is in the low-resistance state, the semi-selected leakage current flowing through the semi-selected cell can be prevented. Consequently, the memory element also functions as a switching element.

When the data in the selected cell is read, the positive-side read voltage Vrp is applied to the selected cell. By detecting change in current or change in potential caused by the difference in flowing current between the case of data “1” and the case of data “0”, the data in the selected cell can be determined.

It is noted that in the case of the eighth operation example, when the data in the selected cell is data “1”, data destruction due to application of the positive-side read voltage Vrp does not occur. In other words, in the case of the eighth operation example, when the data in the selected cell is data “1”, nondestructive read can be performed.

On the other hand, when the data in the selected cell is data “0”, there is a possibility that by applying the positive-side read voltage Vrp higher than the second positive voltage side threshold voltage Vtnp, current flows, and the data in the selected cell changes to data “1”. In other words, in the case of the eighth operation example, when the data in the selected cell is data “0”, destructive read possibly occurs. Consequently, when the data in the selected cell is data “0”, there is a possibility that rewriting of data “0” is required to maintain the data in the selected cell after data is read from the selected cell.

In each of the storage devices according to the fifth embodiment and its modifications, the memory element of the memory cell MC has the switching function, and also has a function of storing information. The memory layer 60 performs the function of the switching layer 40 and the function of the resistive layer 50 in the first embodiment with a single layer. The memory layer 60 in the fifth embodiment has the switching function and the memory function with a single layer, thereby allowing the structure of the memory cell MC to be a simple structure.

The memory layer 60 of each of the storage devices according to the fifth embodiment and its modifications has a configuration similar to that of the switching layer 40 in the first embodiment. Consequently, according to the fifth embodiment and its modifications, similar to the first embodiment, the storage device that has excellent switching characteristics having a low semi-selected leakage current and high reliability can be achieved.

It is noted that a plurality of current-voltage characteristics of the memory elements described in the fifth embodiment and its modifications can be achieved by adopting the memory layer 60 that has an appropriate chemical composition, for example.

### Sixth Embodiment

A storage device in a sixth embodiment includes a memory cell that includes: a first conductive layer; a second conductive layer; and a memory layer that is provided between first conductive layer and the second conductive layer, and includes a first region that includes a second portion in contact with the first conductive layer, a third portion in contact with the second conductive layer, and a first portion between the second portion and the third portion, and a second region that surrounds the first region. The memory layer contains a first element, and an oxide, a nitride, or an oxynitride of a second element. The first element is at least one element selected from a group consisting of tellurium (Te), selenium (Se), sulfur (S), antimony (Sb), and arsenic (As). The second element is at least one element selected from a group consisting of zirconium (Zr), aluminum (Al), hafnium (Hf), yttrium (Y), tantalum (Ta), lanthanum (La), cerium (Ce), magnesium (Mg), silicon (Si), boron (B), phosphorus (P), germanium (Ge), scandium (Sc), vanadium (V), niobium (Nb), chromium (Cr), and titanium (Ti). The atomic concentration of the first element in the first region is higher than the atomic concentration of the first element in the second region. In a first cross section parallel to a first direction connecting the first conductive layer and the second conductive layer, a first length of the first portion in a second direction perpendicular to the first direction is shorter than a second length of the second portion in the second direction, and a third length of the third portion in the second direction.

The storage device according to the sixth embodiment further includes a plurality of first lines, and a plurality of second lines that intersect the plurality of first lines. The memory cell is provided in a region where one of the plurality of first lines intersects one of the plurality of second lines.

The storage device according to the sixth embodiment is different from the storage device according to the second embodiment in that the memory cell does not include the third conductive layer and the resistive layer, and has a configuration similar to that of the switching layer in the second embodiment as the memory layer. The storage device according to the sixth embodiment is different from the storage device according to the fifth embodiment in that the memory layer has a configuration similar to that of the switching layer in the second embodiment. Hereinafter, the redundant description in the second embodiment and the fifth embodiment is partially omitted.

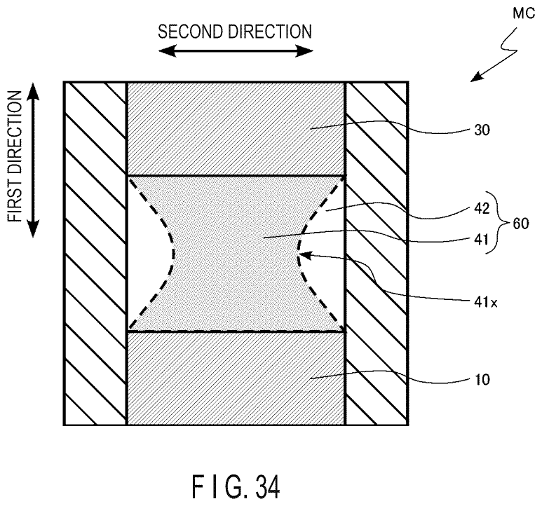

FIG. 34 is a cross sectional diagram schematically illustrating the memory cell of the storage device according to the sixth embodiment. FIG. 34 shows a cross section of one memory cell MC indicated by, for example, a broken-line circle in the memory cell array 100 in FIG. 1.

As shown in FIG. 34, the memory cell MC includes the lower electrode 10, the upper electrode 20, and the memory layer 60.

The lower electrode 10 is an example of a first conductive layer. The upper electrode 20 is an example of a second conductive layer. The lower electrode 10, the memory layer 60, and the upper electrode 20 constitute a memory element of the memory cell MC. The memory element of the memory cell MC has a switching function, and also has a function of storing information.

The memory layer 60 has a configuration similar to that of the switching layer 40 in the second embodiment. That is, the memory layer 60 includes: a first region 41 that includes a contracted portion 41x; and a second region 42 that surrounds the first region 41. The contracted portion 41x is an example of a first portion. The memory layer 60 contains a first element, and an oxide, a nitride, or an oxynitride of a second element. The first element is at least one element selected from a group consisting of tellurium (Te), selenium (Se), sulfur (S), antimony (Sb), and arsenic (As). The second element is at least one element selected from a group consisting of zirconium (Zr), aluminum (Al), hafnium (Hf), yttrium (Y), tantalum (Ta), lanthanum (La), cerium (Ce), magnesium (Mg), silicon (Si), boron (B), phosphorus (P), germanium (Ge), scandium (Sc), vanadium (V), niobium (Nb), chromium (Cr), and titanium (Ti). The atomic concentration of the first element in the first region 41 is higher than the atomic concentration of the first element in the second region 42.

In the storage device according to the sixth embodiment, the memory element of the memory cell MC has the switching function, and also has a function of storing information. The memory layer 60 performs the function of the switching layer 40 and the function of the resistive layer 50 in the second embodiment with a single layer. The memory layer 60 in the sixth embodiment has the switching function and the memory function with a single layer, thereby allowing the structure of the memory cell MC to be a simple structure.

The memory layer 60 of the storage device according to the sixth embodiment has a configuration similar to that of the switching layer 40 in the second embodiment. Consequently, according to the sixth embodiment, similar to the second embodiment, the storage device that has excellent switching characteristics having a low semi-selected leakage current and high reliability can be achieved.

In the first and second embodiments, description is made using the example of the magnetoresistive memory as the two-terminal storage device, and in the third and fourth embodiments, description is made using the example of the resistive memory as the storage device. Alternatively, the present invention is also applicable to other two-terminal storage devices. For example, the present invention is applicable to a phase change memory (PCM), or a ferroelectric random access memory (FeRAM).

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A storage device comprising a memory cell including:
a first conductive layer;
a second conductive layer;
a third conductive layer provided between the first conductive layer and the second conductive layer;
a switching layer that is provided between the first conductive layer and the third conductive layer, and includes a first portion, a second portion in contact with the first conductive layer, and a third portion in contact with the third conductive layer, the first portion being between the second portion and the third portion; and
a resistive layer provided between the third conductive layer and the second conductive layer, wherein
the switching layer contains a first element, and an oxide, a nitride, or an oxynitride of a second element, or the switching layer contains the first element and a third element,
the first element is at least one element selected from a group consisting of tellurium (Te), selenium (Se), sulfur (S), antimony (Sb), and arsenic (As),
the second element is at least one element selected from a group consisting of zirconium (Zr), aluminum (Al), hafnium (Hf), yttrium (Y), tantalum (Ta), lanthanum (La), cerium (Ce), magnesium (Mg), silicon (Si), boron (B), phosphorus (P), germanium (Ge), scandium (Sc), vanadium (V), niobium (Nb), chromium (Cr), and titanium (Ti),
the third element is at least one element selected from a group consisting of zinc (Zn), tin (Sn), gallium (Ga), indium (In), bismuth (Bi), and magnesium (Mg), and
in a first cross section parallel to a first direction from the first conductive layer to the second conductive layer, a first length of the first portion in a second direction perpendicular to the first direction is shorter than a second length of the second portion in the second direction, and shorter than a third length of the third portion in the second direction.

2. The storage device according to claim 1, wherein the switching layer contains: the first element; the oxide, the nitride, or the oxynitride of the second element; and the third element.

3. The storage device according to claim 1, wherein the first length is equal to or shorter than 70% of the second length and equal to or shorter than 70% of the third length.

4. The storage device according to claim 1, wherein in a second cross section perpendicular to the first direction, a first area of the first portion is smaller than a second area of the second portion and smaller than a third area of the third portion.

5. The storage device according to claim 4, wherein the first area is equal to or smaller than 50% of the second area and equal to or smaller than 50% of the third area.

6. The storage device according to claim 1, wherein the switching layer includes a plurality of the first portions.

7. The storage device according to claim 1, wherein in the first cross section, an atomic concentration of the first element in the first portion is different from an atomic concentration of the first element in the second portion and from an atomic concentration of the first element in the third portion.

8. The storage device according to claim 1, wherein the first conductive layer, the second conductive layer, or the third conductive layer contains at least one substance selected from a group consisting of carbon, carbon nitride, tungsten, tungsten carbide, tungsten nitride, titanium, titanium nitride, tantalum, tantalum carbide, and tantalum nitride.

9. The storage device according to claim 1, wherein the resistive layer includes a magnetic tunnel junction.

10. The storage device according to claim 1, wherein
the resistive layer has an electrical resistance that changes with application of a predetermined voltage, and
the switching layer has nonlinear current-voltage characteristics in which current rises at a specific threshold voltage.

11. The storage device according to claim 1, further comprising:
a plurality of first lines; and
a plurality of second lines each of which intersects the plurality of first lines,
wherein the memory cell is provided in a region where one of the plurality of first lines intersects one of the plurality of second lines.

12. A storage device comprising a memory cell including:
a first conductive layer;
a second conductive layer;
a third conductive layer provided between the first conductive layer and the second conductive layer;
a switching layer that is provided between the first conductive layer and the third conductive layer, and includes: a first region that includes a first portion, a second portion in contact with the first conductive layer, and a third portion in contact with the third conductive layer, the first portion being between the second portion and the third portion; and a second region that surrounds the first region; and
a resistive layer provided between the third conductive layer and the second conductive layer, wherein
the switching layer contains a first element, and an oxide, a nitride, or an oxynitride of a second element,
the first element is at least one element selected from a group consisting of tellurium (Te), selenium (Se), sulfur (S), antimony (Sb), and arsenic (As),
the second element is at least one element selected from a group consisting of zirconium (Zr), aluminum (Al), hafnium (Hf), yttrium (Y), tantalum (Ta), lanthanum (La), cerium (Ce), magnesium (Mg), silicon (Si), boron (B), phosphorus (P), germanium (Ge), scandium (Sc), vanadium (V), niobium (Nb), chromium (Cr), and titanium (Ti),
an atomic concentration of the first element in the first region is higher than an atomic concentration of the first element in the second region, and
in a first cross section parallel to a first direction from the first conductive layer to the second conductive layer, a first length of the first portion in a second direction perpendicular to the first direction is shorter than a second length of the second portion in the second direction, and shorter than a third length of the third portion in the second direction.

13. The storage device according to claim 12, wherein the switching layer further contains a third element, and the third element is at least one element selected from a group consisting of zinc (Zn), tin (Sn), gallium (Ga), indium (In), bismuth (Bi), and magnesium (Mg).

14. The storage device according to claim 12, wherein the first length is equal to or shorter than 70% of the second length and equal to or shorter than 70% of the third length.

15. The storage device according to claim 12, wherein in a second cross section perpendicular to the first direction, a first area of the first portion is smaller than a second area of the second portion and smaller than a third area of the third portion.

16. The storage device according to claim 15, wherein the first area is equal to or smaller than 50% of the second area and equal to or smaller than 50% of the third area.

17. The storage device according to claim 12, wherein the first conductive layer, the second conductive layer, or the third conductive layer contains at least one substance selected from a group consisting of carbon, carbon nitride, tungsten, tungsten carbide, tungsten nitride, titanium, titanium nitride, tantalum, tantalum carbide, and tantalum nitride.

18. The storage device according to claim 12, wherein the resistive layer includes a magnetic tunnel junction.

19. The storage device according to claim 12, wherein
the resistive layer has an electrical resistance that changes with application of a predetermined voltage, and
the switching layer has nonlinear current-voltage characteristics in which current rises at a specific threshold voltage.

20. The storage device according to claim 12, further comprising:
a plurality of first lines; and
a plurality of second lines each of which intersects the plurality of first lines,
wherein the memory cell is provided in a region where one of the plurality of first lines intersects one of the plurality of second lines.

21. A storage device comprising a memory cell including:
a first conductive layer;
a second conductive layer; and
a memory layer that is provided between the first conductive layer and the second conductive layer, and includes a first portion, a second portion in contact with the first conductive layer, and a third portion in contact with the second conductive layer, the first portion being between the second portion and the third portion, wherein
the memory layer contains a first element, and an oxide, a nitride, or an oxynitride of a second element, or the memory layer contains the first element and a third element,
the first element is at least one element selected from a group consisting of tellurium (Te), selenium (Se), sulfur (S), antimony (Sb), and arsenic (As),
the second element is at least one element selected from a group consisting of zirconium (Zr), aluminum (Al), hafnium (Hf), yttrium (Y), tantalum (Ta), lanthanum (La), cerium (Ce), magnesium (Mg), silicon (Si), boron (B), phosphorus (P), germanium (Ge), scandium (Sc), vanadium (V), niobium (Nb), chromium (Cr), and titanium (Ti),
the third element is at least one element selected from a group consisting of zinc (Zn), tin (Sn), gallium (Ga), indium (In), bismuth (Bi), and magnesium (Mg), and
in a first cross section parallel to a first direction from the first conductive layer to the second conductive layer, a first length of the first portion in a second direction perpendicular to the first direction is shorter than a second length of the second portion in the second direction, and shorter than a third length of the third portion in the second direction.

22. The storage device according to claim 21, wherein the memory layer contains: the first element;
the oxide, the nitride, or the oxynitride of the second element; and the third element.

23. The storage device according to claim 21, wherein in a second cross section perpendicular to the first direction, a first area of the first portion is smaller than a second area of the second portion and smaller than a third area of the third portion.

24. The storage device according to claim 21, wherein the memory layer has nonlinear current-voltage characteristics in which current rises at a specific threshold voltage, and the threshold voltage changes with application of a predetermined voltage.

25. The storage device according to claim 21, further comprising:
a plurality of first lines; and
a plurality of second lines each of which intersects the plurality of first lines,
wherein the memory cell is provided in a region where one of the plurality of first lines intersects one of the plurality of second lines.

26. A storage device comprising a memory cell including:
a first conductive layer;
a second conductive layer; and
a memory layer that is provided between the first conductive layer and the second conductive layer, and includes: a first region that includes a first portion, a second portion in contact with the first conductive layer, and a third portion in contact with the second conductive layer, the first portion being between the second portion and the third portion; and a second region that surrounds the first region,
wherein the memory layer contains a first element, and an oxide, a nitride, or an oxynitride of a second element,
the first element is at least one element selected from a group consisting of tellurium (Te), selenium (Se), sulfur (S), antimony (Sb), and arsenic (As),
the second element is at least one element selected from a group consisting of zirconium (Zr), aluminum (Al), hafnium (Hf), yttrium (Y), tantalum (Ta), lanthanum (La), cerium (Ce), magnesium (Mg), silicon (Si), boron (B), phosphorus (P), germanium (Ge), scandium (Sc), vanadium (V), niobium (Nb), chromium (Cr), and titanium (Ti),
an atomic concentration of the first element in the first region is higher than an atomic concentration of the first element in the second region, and
in a first cross section parallel to a first direction from the first conductive layer to the second conductive layer, a first length of the first portion in a second direction perpendicular to the first direction is shorter than a second length of the second portion in the second direction, and shorter than a third length of the third portion in the second direction.

27. The storage device according to claim 26, wherein the memory layer further contains a third element, and the third element is at least one element selected from a group consisting of zinc (Zn), tin (Sn), gallium (Ga), indium (In), bismuth (Bi), and magnesium (Mg).

28. The storage device according to claim 26, wherein in a second cross section perpendicular to the first direction, a first area of the first portion is smaller than a second area of the second portion and smaller than a third area of the third portion.

29. The storage device according to claim 26, wherein the memory layer has nonlinear current-voltage characteristics in which current rises at a specific threshold voltage, and the threshold voltage changes with application of a predetermined voltage.

30. The storage device according to claim 26, further comprising:
a plurality of first lines; and
a plurality of second lines each of which intersects the plurality of first lines,
wherein the memory cell is provided in a region where one of the plurality of first lines intersects one of the plurality of second lines.
